(19) United States
(12) Patent Application Publication
(10) Pub. No.: US 2025/0140521 A1
(43) Pub. Date: May 1, 2025

(54) MULTIPLE CHARGED PARTICLE BEAM WRITING METHOD AND MULTIPLE CHARGED PARTICLE BEAM WRITING APPARATUS

(71) Applicant: NuFlare Technology, Inc., Yokohama-shi (JP)

(72) Inventor: Hiroshi MATSUMOTO, Yokohama-shi (JP)

(73) Assignee: NuFlare Technology, Inc., Yokohama-shi (JP)

(21) Appl. No.: 18/919,547

(22) Filed: Oct. 18, 2024

(30) Foreign Application Priority Data
Oct. 31, 2023 (JP) 2023-186510

(51) Int. Cl. H01J 37/304; H01J 37/20; H01J 37/317

(52) U.S. Cl. CPC H01J 37/3045; H01J 37/20; H01J 37/3177; H01J 2237/1536; H01J 2237/202

(57) ABSTRACT

A multiple charged particle beam writing method includes emitting multiple charged particle beams, and performing writing with the multiple charged particle beams, during a movement of a stage having a target object thereon in a reverse direction to a movement direction of the writing, to at least two stripe regions in a plurality of stripe regions aligned, on the target object, partially overlapping with each other in the first direction being linearly independent with respect to the movement direction of the writing, while repeatedly switching an irradiation region, in the first direction, by a deflection amount having a width larger than a beam pitch size of the multiple charged particle beams, and applying irradiation with the multiple charged particle beams at each time of the switching the irradiation region.

### CROSS-REFERENCE TO RELATED APPLICATION

This application is based upon and claims the benefit of priority from prior Japanese Patent Application No. 2023-186510 filed on Oct. 31, 2023 in Japan, the entire contents of which are incorporated herein by reference.

### BACKGROUND OF THE INVENTION

### Field of the Invention

Embodiments of the present invention relate to a multiple charged particle beam writing method and a multiple charged particle beam writing apparatus, and, for example, to a method for correcting a position deviation of a beam array occurring on the substrate surface of a multiple beam writing apparatus.

### Description of Related Art

The lithography technique which advances miniaturization of semiconductor devices is extremely important as a unique process whereby patterns are formed in semiconductor manufacturing. In recent years, with high integration of LSI, the line width (critical dimension) necessary for semiconductor device circuits is becoming increasingly narrower year by year. The electron beam writing technique, which intrinsically has excellent resolution, is used for writing or “drawing” patterns on a wafer and the like with electron beams.

For example, as a known example of employing the electron beam writing technique, there is a writing apparatus using multiple beams. Since writing with multiple beams can apply a lot of beams at a time, the writing throughput can be greatly increased compared to writing with a single electron beam. For example, a writing apparatus employing the multiple-beam system forms multiple beams by letting an electron beam emitted from an electron gun pass through a mask having a plurality of holes, performs blanking control for each beam, reduces each unblocked beam to generate a reduced mask image by an optical system, and deflects, by a deflector, a reduced beam to be applied to a desired position on a target object or “sample”.

With regard to the multiple beam writing, it is important for the writing accuracy to highly accurately connect (combine) beam arrays each other for being applied to the substrate. Accordingly, before writing, mark scanning is performed in order to measure a beam array shape on the substrate. As linear components of the beam array shape, there are, for example, a YY linear component indicating a displacement in the y direction, and an XY linear component indicating an oblique displacement which is shifted in the x direction while maintaining the y direction. Their averaging effect can be enhanced by increasing the number of passes (multiplicity) of multiple writing performed while shifting (displacing) the irradiation region in the y direction at each completion of writing to the stripe region. However, for example, if the number of passes of multiple writing is doubled, the moving (running) distance of the stage becomes twice. When aiming to avoid an increase in the writing time, it is necessary to double the stage speed and to halve the y-direction moving (running) time of the stage. Further, if the moving distance of the stage increases, there is a possibility that the writing accuracy degrades due to a vibration increase along with the stage movement. Furthermore, deterioration of the stage mechanism is accelerated when the moving distance of the stage increases, and thus, the maintenance cycle may become short.

With regard to variable-shaped beam (VSB) writing using a single beam, there is disclosed a method of alternately repeating the first writing and the second writing during a stage movement (e.g., refer to Japanese Patent Application Laid-open (JP-A) No. 2012-043972). When it moves from the first writing position to the second writing position, beam deflection of a large deflection amount is needed. If the beam deflection becomes large, a problem occurs in that the position deviation resulting from the beam deflection is generated. Then, in the VSB writing, such a problem can be coped with by correcting each shot position individually. In contrast, however, in the multiple beam writing, it is difficult to correct each beam shot position individually.

### BRIEF SUMMARY OF THE INVENTION

According to one aspect of the present invention, a multiple charged particle beam writing method includes emitting multiple charged particle beams; and performing writing with the multiple charged particle beams, during a movement of a stage having a target object thereon in a reverse direction to a movement direction of the writing, to at least two stripe regions in a plurality of stripe regions aligned, on the target object, partially overlapping with each other in a first direction being linearly independent with respect to the movement direction of the writing, while repeatedly switching an irradiation region, in the first direction, by a deflection amount having a width larger than a beam pitch size of the multiple charged particle beams, and applying irradiation with the multiple charged particle beams at each time of the switching the irradiation region.

According to another aspect of the present invention, a multiple charged particle beam writing apparatus includes

a writing mechanism configured to include a beam source which emits multiple charged particle beams, a stage on which a target object is mounted, and a deflector which deflects the multiple charged particle beams, and configured to perform writing with the multiple charged particle beams, during a movement of the stage having the target object thereon in a reverse direction to a movement direction of the writing, to at least two stripe regions in a plurality of stripe regions aligned, on the target object, partially overlapping with each other in a first direction being linearly independent with respect to the movement direction of the writing, while repeatedly switching an irradiation region, in the first direction, by a deflection amount having a width larger than a beam pitch size of the multiple charged particle beams, and applying irradiation with the multiple charged particle beams at each time of the switching the irradiation region; and

a control circuit configured to control the writing mechanism.

### BRIEF DESCRIPTION OF THE DRAWINGS

FIG. 1 is an illustration showing a configuration schematic diagram of a writing apparatus according to a first embodiment;

FIG. 2 is a conceptual diagram showing a configuration of a shaping aperture array substrate according to the first embodiment;

FIG. 3 is a sectional view showing a configuration of a blanking aperture array mechanism according to the first embodiment;

FIG. 4 is a conceptual diagram showing an example of writing operations according to the first embodiment;

FIG. 5 is an illustration showing a parameter of a linear component according to the first embodiment;

FIGS. 6A and 6B are illustrations for explaining multiple writing performed with shifting according to a comparative example of the first embodiment;

FIGS. 7A to 7C are illustrations for explaining an example of averaging a y-direction position shift amount according to the first embodiment;

FIG. 8 is a flowchart showing an example of main steps of a writing method according to the first embodiment;

FIG. 9 is an illustration showing a time chart of a main deflection, magnification correction and phase correction, as an example of a writing sequence, according to the first embodiment;

FIG. 10 is an illustration showing a time chart of a main deflection and a sub deflection, as an example of a writing sequence, according to the first embodiment;

FIGS. 11A to 11C are illustrations each showing a part of an example of a writing sequence according to the first embodiment;

FIGS. 12A to 12C are illustrations each showing another part of an example of a writing sequence according to the first embodiment;

FIGS. 13A to 13C are illustrations each showing another part of an example of a writing sequence according to the first embodiment;

FIG. 14 is an illustration describing a method of multiple writing according to a comparative example 1 of the first embodiment 1;

FIG. 15 is an illustration describing a method of multiple writing according to an example of a writing sequence of the first embodiment;

FIG. 16 is an illustration describing a distortion resulting from Y deflection and a distortion correction according to the first embodiment;

FIG. 17 is an illustration showing a time chart of a main deflection and a sub deflection, as another example of a writing sequence, according to the first embodiment;

FIGS. 18A and 18B are illustrations each showing a part of another example of a writing sequence according to the first embodiment;

FIGS. 19A and 19B are illustrations each showing a part of another example of a writing sequence according to the first embodiment;

FIG. 20 is an illustration describing a method of multiple writing according to a comparative example 2 of the first embodiment;

FIG. 21 is an illustration describing a method of multiple writing according to another example of a writing sequence of the first embodiment; and

FIGS. 22A to 22C are illustrations explaining a configuration of a deflector according to the first embodiment.

### DETAILED DESCRIPTION OF THE INVENTION

Embodiments below provide a writing method and writing apparatus that can reduce, while suppressing an increase in a stage moving distance, a position deviation due to displacement of a linear component of a beam array shape in multiple beam writing.

The embodiments below describe a configuration in which an electron beam is used as an example of a charged particle beam. The charged particle beam is not limited to the electron beam, and other charged particle beams such as an ion beam may also be used.

### First Embodiment

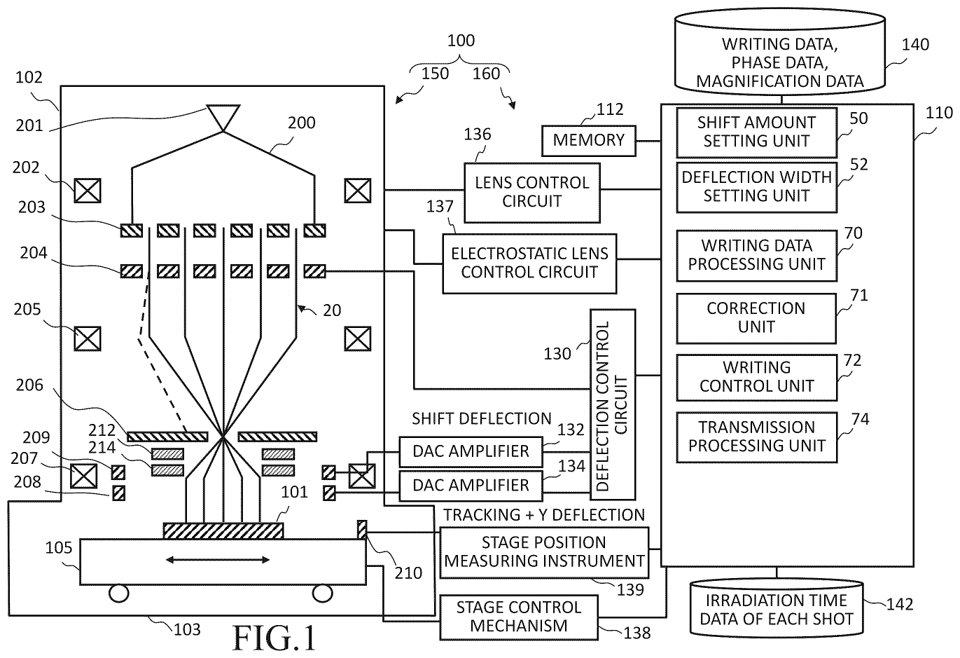

FIG. 1 is an illustration showing a configuration schematic diagram of a writing or “drawing” apparatus according to a first embodiment. As shown in FIG. 1, a writing apparatus 100 includes a writing mechanism 150 and a control system circuit 160. The writing apparatus 100 is an example of a multiple charged particle beam writing apparatus, and a multiple charged particle beam exposure apparatus. The writing mechanism 150 includes an electron optical column 102 (electron beam column) and a writing chamber 103. In the electron optical column 102, there are disposed an electron gun 201, an illumination lens 202, a shaping aperture array substrate 203, a blanking aperture array mechanism 204, a reducing lens 205, a limiting aperture substrate 206, electrostatic lenses 212 and 214, an objective lens 207, a main deflector 208, and a sub deflector 209.

In the writing chamber 103, an XY stage 105 is disposed. On the XY stage 105, there is placed a target object or “sample” 101 such as a mask serving as a writing target substrate when writing (exposure) is performed. The target object 101 is, for example, an exposure mask used in fabricating semiconductor devices, or a semiconductor substrate (silicon wafer) for fabricating semiconductor devices. Further, the target object 101 may be, for example, a mask blank on which resist has been applied and nothing has yet been written. On the XY stage 105, a mirror 210 for measuring the position of the XY stage 105 is placed.

The control system circuit 160 includes a control computer 110, a memory 112, a deflection control circuit 130, DAC (digital-analog converter) amplifier units 132 and 134, a lens control circuit 136, an electrostatic lens control circuit 137, a stage control mechanism 138, a stage position measuring instrument 139, and storage devices 140 and 142 such as magnetic disk drives. The control computer 110, the memory 112, the deflection control circuit 130, the lens control circuit 136, the electrostatic lens control circuit 137, the stage control mechanism 138, the stage position measuring instrument 139, and the storage devices 140 and 142 are connected to each other through a bus (not shown). The DAC amplifier units 132 and 134 and the blanking aperture array mechanism 204 are connected to the deflection control circuit 130. The sub deflector 209 is composed of at least four electrodes (or “at least four poles”), and controlled by the deflection control circuit 130 through the DAC amplifier unit 132 disposed for each electrode. The main deflector 208 is composed of at least four electrodes (or “at least four poles”), and controlled by the deflection control circuit 130 through the DAC amplifier unit 134 disposed for each electrode. Lenses such as the illumination lens 202, the reducing lens 205, and the objective lens 207 are controlled by the lens control circuit 136.

The electrostatic lens 212 is composed of electrode substrates of three or more stages (not shown) each having an opening through which multiple beams 20 can pass. For example, the electrostatic lens 212 is composed of electrode substrates of three stages: the upper and lower stages where a grand potential is applied and the middle stage where a control potential is applied. Similarly, the electrostatic lens 214 is composed of electrode substrates of three or more stages (not shown) each having an opening through which multiple beams 20 can pass. For example, the electrostatic lens 214 is composed of electrode substrates of three stages: the upper and lower stages where a grand potential is applied and the middle stage where a control potential is applied. The electrostatic lenses 212 and 214 are controlled by the electrostatic lens control circuit 137.

The position of the XY stage 105 is controlled by the drive of each axis motor (not shown) which is controlled by the stage control mechanism 138. Based on the principle of laser interferometry, the stage position measurement instrument 139 measures the position of the XY stage 105 by receiving a reflected light from the mirror 210.

In the control computer 110, there are arranged a shift amount setting unit 50, a deflection width setting unit 52, a writing data processing unit 70, a correction unit 71, a writing control unit 72, and a transmission processing unit 74. Each of the “ . . . units” such as the shift amount setting unit 50, the deflection width setting unit 52, the writing data processing unit 70, the correction unit 71, the writing control unit 72, and the transmission processing unit 74 includes processing circuitry. The processing circuitry includes, for example, an electric circuit, a computer, a processor, a circuit board, a quantum circuit, a semiconductor device, or the like. Each “ . . . unit” may use common processing circuitry (the same processing circuitry), or different processing circuitry (separate processing circuitry). Information input/output to/from the shift amount setting unit 50, the deflection width setting unit 52, the writing data processing unit 70, the correction unit 71, the writing control unit 72, and the transmission processing unit 74, and information being operated are stored in the memory 112 each time.

Writing operations of the writing apparatus 100 are controlled by the writing control unit 72. In other words, the writing control unit 72 (an example of a control circuit) controls the writing mechanism 150. Processing of transmitting irradiation time data of each shot to the deflection control circuit 130 is controlled by the transmission control unit 74.

Writing data (chip data) is input from the outside of the writing apparatus 100, and stored in the storage device 140. Chip data defines information on a plurality of figure patterns configuring a chip pattern. Specifically, for example, a figure code, coordinates, a size, and the like are defined for each figure pattern.

FIG. 1 shows a configuration necessary for describing the first embodiment. Other configuration elements generally necessary for the writing apparatus 100 may also be included therein.

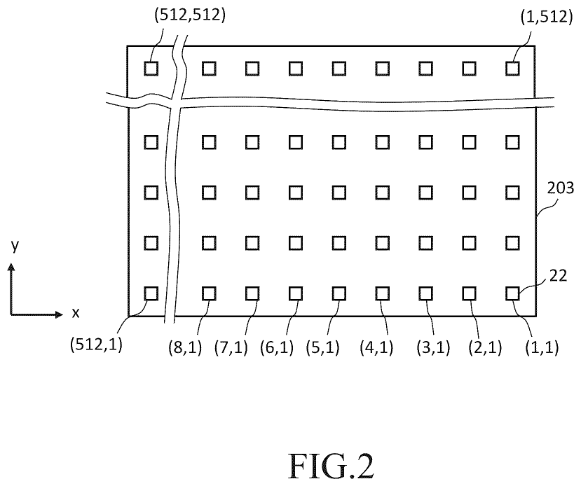

FIG. 2 is a conceptual diagram showing a configuration of a shaping aperture array substrate according to the first embodiment. As shown in FIG. 2, holes (openings) 22 of p rows long (length in the y direction) and q columns wide (width in the x direction) (p≥2, q≥2) are formed, like a matrix, at a predetermined arrangement pitch in the shaping aperture array substrate 203. In the case of FIG. 2, for example, holes (openings) 22 of 512×512, that is 512 holes in the y direction and 512 holes in the x direction, are formed. The number of holes 22 is not limited thereto. For example, it is also preferable to form the holes 22 of 32×32. Each of the holes 22 is a rectangle (including square) having the same dimension and shape as each other. Alternatively, each of the holes 22 may be a circle with the same diameter as each other. The multiple beams 20 are formed by letting portions of an electron beam 200 individually pass through a corresponding one of a plurality of holes 22. In other words, the shaping aperture array substrate 203 forms the multiple beams 20.

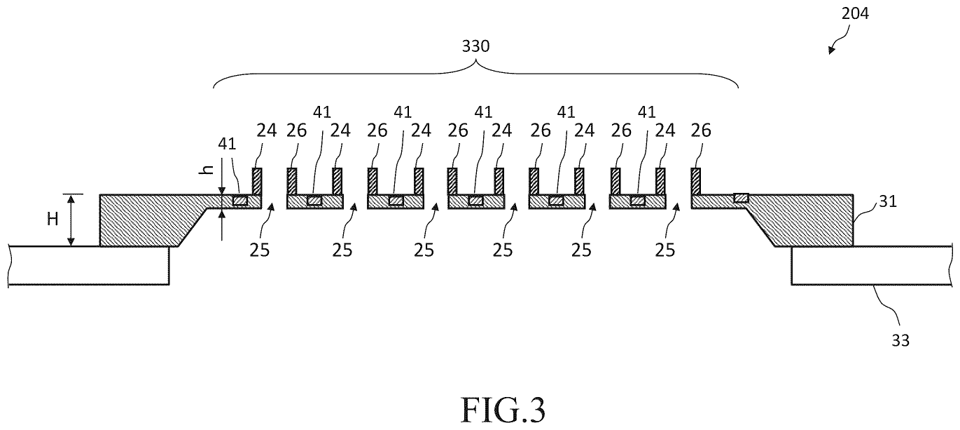

FIG. 3 is a sectional view showing a configuration of a blanking aperture array mechanism according to the first embodiment. In the blanking aperture array mechanism 204, as shown in FIG. 3, a blanking aperture array substrate 31 being a semiconductor substrate made of silicon, etc. is disposed on a support table 33. In a membrane region 330 at the center of the blanking aperture array substrate 31, a plurality of passage holes 25 (openings), through each of which a corresponding one of the multiple beams 20 passes, are formed at positions each corresponding to each hole 22 in the shaping aperture array substrate 203 shown in FIG. 2. A pair of a control electrode 24 and a counter electrode 26, (blanker: blanking deflector), is arranged in a manner such that the electrodes 24 and 26 are opposite to each other across a corresponding one of the plurality of the passage holes 25. A control circuit 41 (logic circuit) which applies a deflection voltage to the control electrode 24 for the passage hole 25 concerned is disposed inside the blanking aperture array substrate 31 and close to each corresponding passage hole 25. The counter electrode 26 for each beam is grounded.

In the control circuit 41, an amplifier (not shown) (an example of a switching circuit) is arranged. As an example of the amplifier, a CMOS (Complementary MOS) inverter circuit serving as a switching circuit is disposed. With regard to inputs (IN) to the CMOS inverter circuit, either an L (low) potential (e.g., ground potential) lower than a threshold voltage, or an H (high) potential (e.g., 1.5 V) higher than or equal to the threshold voltage is applied as a control signal. According to the first embodiment, in a state where an L potential is applied to the input (IN) of the CMOS inverter circuit, the output (OUT) of the CMOS inverter circuit, which is to be applied to the control circuit 41, becomes a positive potential (Vdd), and then, a corresponding beam is deflected by an electric field due to a potential difference from the ground potential of the counter electrode 26, and is controlled to be in a beam OFF condition by being blocked by the limiting aperture substrate 206. In contrast, in a state (active state) where an H potential is applied to the input (IN) of the CMOS inverter circuit, the output (OUT) of the CMOS inverter circuit becomes a ground potential, and therefore, since there is no potential difference from the ground potential of the counter electrode 26, a corresponding beam is not deflected, and is controlled to be in a beam ON condition by passing through the limiting aperture substrate 206. Blanking control is provided by such deflection.

Next, operations of the writing mechanism 150 will be described. The electron beam 200 emitted from the electron gun 201 (emission source) almost perpendicularly (e.g., vertically) illuminates the whole of the shaping aperture array substrate 203 by the illumination lens 202. A plurality of rectangular holes 22 (openings) are formed in the shaping aperture array substrate 203. The region including all of the plurality of holes 22 is irradiated with the electron beam 200. For example, rectangular multiple beams (a plurality of electron beams) 20 are formed by letting portions of the electron beam 200 applied to the positions of the plurality of holes 22 individually pass through a corresponding one of the plurality of holes 22 in the shaping aperture array substrate 203. The multiple beams 20 individually pass through corresponding blankers of the blanking aperture array mechanism 204. The blanker provides blanking control such that a corresponding beam individually passing becomes in an ON condition during a set writing time (irradiation time).

The multiple beams 20 having passed through the blanking aperture array mechanism 204 are reduced by the reducing lens 205, and travel toward the hole in the center of the limiting aperture substrate 206. Then, the electron beam which was deflected by the blanker of the blanking aperture array mechanism 204 deviates from the hole in the center of the limiting aperture substrate 206 and is blocked by the limiting aperture substrate 206. In contrast, the electron beam which was not deflected by the blanker of the blanking aperture array mechanism 204 passes through the hole in the center of the limiting aperture substrate 206 as shown in FIG. 1. Thus, the limiting aperture substrate 206 blocks each beam which was deflected to be in the OFF state by the blanker of the blanking aperture array mechanism 204. Then, each beam for one shot by the multiple beams 20 is formed by a beam which has been made during a period from becoming beam ON to becoming beam OFF and has passed through the limiting aperture substrate 206. The multiple beams 20 having passed through the limiting aperture substrate 206 are focused by the objective lens 207 so as to be a pattern image of a desired reduction ratio. Then, all of the multiple beams 20 having passed through the limiting aperture substrate 206 are collectively deflected in the same direction by the deflectors 208 and 209 in order to irradiate respective beam irradiation positions on the target object 101. For example, when the XY stage 105 is continuously moving, tracking control is performed by the deflector 208 so that the beam irradiation position may follow the movement of the XY stage 105. Ideally, the multiple beams 20 irradiating at a time are aligned at the pitch obtained by multiplying the arrangement pitch of a plurality of holes 22 in the shaping aperture array substrate 203 by the desired reduction ratio described above.

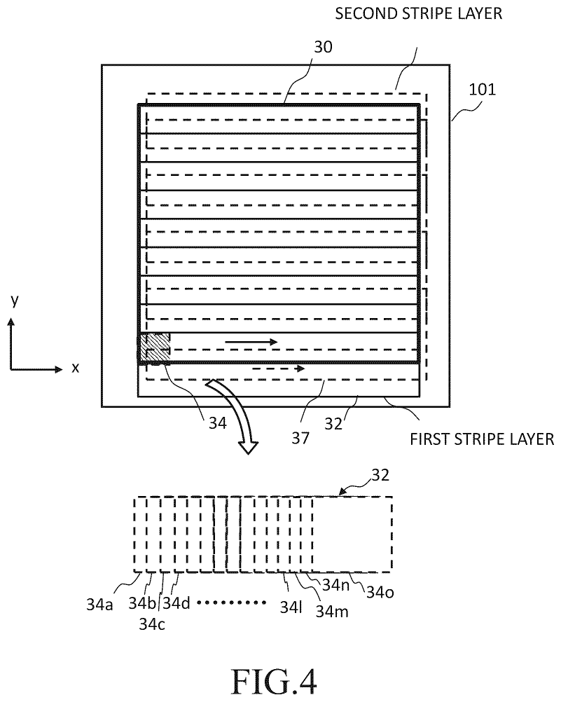

FIG. 4 is a conceptual diagram showing an example of writing operations according to the first embodiment. As shown in FIG. 4, a writing region 30 (bold line) of the target object 101 is virtually divided into a plurality of stripe regions 32 by a predetermined width in the y direction, for example. In the case of FIG. 4, the writing region 30 of the target object 101 is divided in the y direction, for example, into a plurality of stripe regions 32 by the width size being substantially the same as the design size of an irradiation region 34 (writing field) which can be irradiated by one irradiation with the multiple beams 20. The x-direction design size of the irradiation region 34 of the multiple beams 20 can be defined by (the number of x-direction beams)×(x-direction beam pitch). The y-direction size of the rectangular irradiation region 34 can be defined by (the number of y-direction beams)×(y-direction beam pitch).

Further, in the case of FIG. 4, there are configured a first stripe layer composed of a plurality of stripe regions 32 obtained by dividing the writing region 30, and a second stripe layer composed of a plurality of stripe regions 37 obtained by shifting (displacing) with respect to the first stripe layer in the y direction by half the dimension of the width of the stripe region 32. Thus, in the example of FIG. 4, two stipe layers of the first stripe layer and the second stripe layer are set. Therefore, by combining the first stripe layer and the second stripe layer, a plurality of stripe regions 32 and 37 are arranged with partially overlapping with each other in the y direction. FIG. 4 shows the case where the stripe regions 32 and 37, adjacent to each other in the y direction, are mutually overlapped by half the amount of each region. Further, it is preferable that one surplus stripe region 32 and one surplus stripe region 37 are set in the −y direction from the end of the writing region 30 in each of the first and second stripe layers. Next, an example of the writing operations will be described.

First, the XY stage 105 is moved to make an adjustment such that the irradiation region 34 of the multiple beams 20 is located at the left end, or at a position further left than the left end, of the first stripe region 32 in the first stripe layer. Then, writing is performed to the first stripe region 32 in the first stripe layer and the first stripe region 37 in the second stripe layer. When performing writing to the first stripe region 32 in the first stripe layer and the first stripe region 37 in the second stripe layer, the XY stage 105 is moved, for example, in the −x direction, so that the writing may relatively proceed in the x direction. The XY stage 105 is moved, for example, continuously at a constant speed. After writing to the first stripe region 32 in the first stripe layer and the first stripe region 37 in the second stripe layer, the stage position is moved in the −y direction by the shift (displacement) amount being the width size of the stripe region 32. Thereby, the stripe region 32 to be written is shifted (displaced) in the y direction by the shift amount being the size of the width of the stripe region 32.

Next, an adjustment is made so that the irradiation region 34 of the multiple beams 20 can be located at the left end, or at a position further left than the left end, of the second stripe region 32 in the first stripe layer. By moving the XY stage 105, for example, in the −x direction, the writing relatively proceeds in the x direction. Thereby, writing is performed to the second stripe region 32 in the first stripe layer and the second stripe region 37 in the second stripe layer. Thus, during one movement (running movement) in the −x direction of the XY stage 105, writing is performed to the k-th stripe region 32 in the first stripe layer and the k-th stripe region 32 in the second stripe layer. That is, during one movement in the −x direction of the XY stage 105, the stripe region 32 in the first stripe layer, which has been displaced in the y direction by half the width dimension of the stripe region 32, and the stripe region 37 in the second stripe layer are alternately written. The switching (changing) of the stripe layer is performed by Y deflection by the main deflector 28 described later. Thereby, double (multiple) writing is performed at the part where the stripe region 32 in the first stripe layer and the stripe region 37 in the second stripe layer are overlapped with each other, whereas no multiple writing (single writing) is performed at the part where no region is overlapped.

According to the first embodiment, two or more stripe regions are written during one movement of the XY stage 105. Here, the case of writing, for example, two stripe regions 32 and 37 will be described. When writing, for example, the two stripe regions 32 and 37, the number of shots is twice that of the case of writing one stripe region 32 (37) during one movement of the XY stage 105. Therefore, it is necessary to set the stage speed to be half compared to the case of writing one stripe region 32 (37) during one movement of the XY stage 105.

Y deflection which shifts, in the y direction, the irradiation region 34 of the multiple beams 20 during writing each stripe region 32 will be described later. In addition, when writing is proceeded in the x direction, multiple writing may further be performed.

FIG. 4 shows the case where each of the stripe regions 32 and 37 is written in the same direction, but, it is not limited thereto. For example, with respect to two stripe regions 32 and 37 to be written following two stripe regions 32 and 37 having already been written in the x direction, they may be written in the −x direction by moving the XY stage 105 in the x direction, for example. Thus, the stage moving time can be reduced by performing writing while alternately changing the writing direction, which results in reducing the writing time. Owing to one shot of multiple beams having been formed by individually passing through the holes 22 in the shaping aperture array substrate 203, a plurality of shot patterns maximally up to as many as the number of the holes 22 are formed at a time.

Although FIG. 4 shows the case where the shift amount in the y direction of each stripe layer is set to be half the width dimension of the stripe region 32, it is not limited thereto. For example, it is also preferable to set four stripe layers which are shifted with each other in the y direction by a quarter of the width dimension of the stripe region 32. Further, other number of stripe layers may also be set.

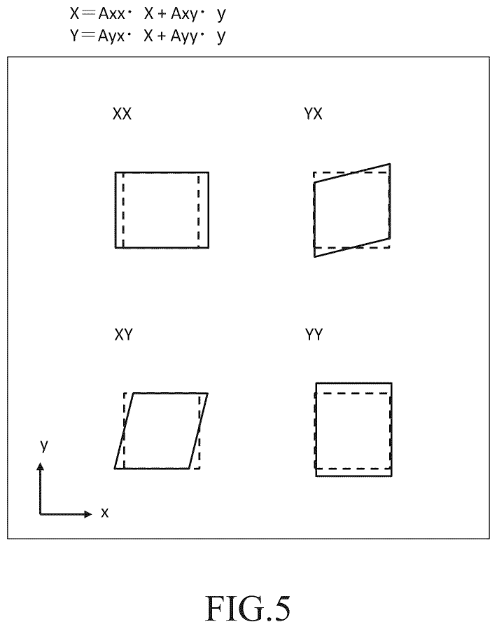

FIG. 5 is an illustration showing a parameter of a linear component according to the first embodiment. In FIG. 5, a design rectangular beam array shape is depicted by a dotted line. The XX linear component indicates an x-direction displacement component which expands (or contracts) in the x direction with respect to the design beam array shape. The YY linear component indicates a y-direction displacement component which expands (or contracts) in the y direction with respect to the design beam array shape. The XY linear component indicates an oblique displacement component which shifts in the x direction while maintaining the y direction with respect to the design beam array shape. The YX linear component indicates an oblique displacement component which shifts in the y direction while maintaining the x direction with respect to the design beam array shape. A_{XX} indicates a linear component parameter depending on an expanding (or contracting) amount in the x direction with respect to the design beam array shape. A_{YY} indicates a linear component parameter depending on an expanding (or contracting) amount in the y direction with respect to the design beam array shape. A_{XY} indicates a linear component parameter depending on an inclination amount of the y-direction expanding side which inclines in the x direction with respect to the design beam array shape. A_{YX} indicates a linear component parameter depending on an inclination amount of the x-direction expanding side which inclines in the y direction with respect to the design beam array shape.

The x-coordinate X of each point in the beam array shape can be approximated by the following equation (1-1) using the design coordinates (x, y). Similarly, the y-coordinate Y of each point in the beam array shape can be approximated by the following equation (1-2) using the design coordinates (x, y).

$$X = {A}_{XX} \cdot x + {A}_{XY} \cdot y \qquad ( 1 - 1 )$$

$$Y = {A}_{YX} \cdot x + {A}_{YY} \cdot y \qquad ( 1 - 2 )$$

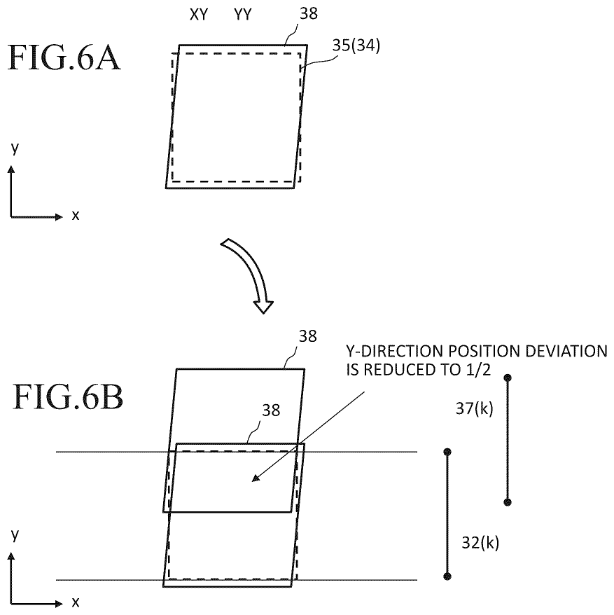

FIGS. 6A and 6B are illustrations for explaining multiple writing performed with shifting according to a comparative example of the first embodiment. In FIG. 6A, a design beam array shape 35 (dotted line) is the same as the shape of the design irradiation region 34 of the multiple beams 20. The example of FIG. 6A shows a beam array shape 38 (solid line) whose linear components YY and XY have been deviated. For example, after writing to the k-th stripe region 32 in the first stripe layer, the k-th stripe region 37 in the second stripe layer is written. Thereby, as shown in FIG. 6B, twice writing (multiple writing) has been performed in the upper half region of the k-th stripe region 32 in the first stripe layer. Thus, the position shift amount in the y direction is averaged by the two-time writing whose irradiation regions are shifted from each other, and is reduced to ½.

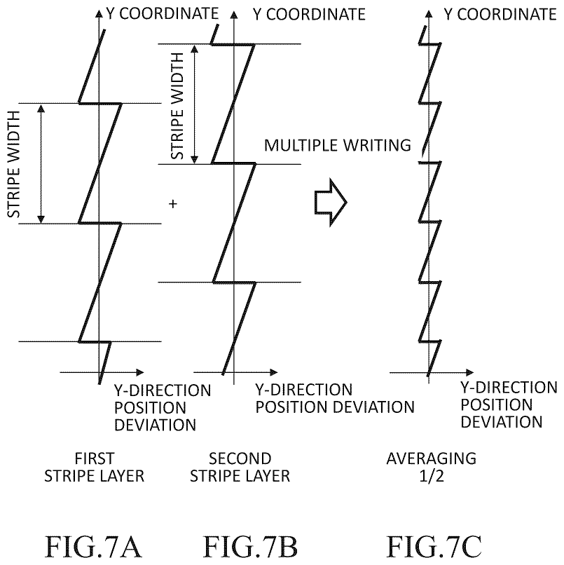

FIGS. 7A to 7C are illustrations for explaining an example of averaging a y-direction position shift amount according to the first embodiment. FIGS. 7A to 7C show the case where multiple writing is performed with the multiple beams 20 of the beam array shape whose linear component YY has been deviated, for example. In the case of the beam array shape in which a position deviation has occurred expanding in the y direction beyond the design shape, no position deviation occurs at the y direction center among positions in the beam array shape. In contrast, at the y direction end, a positive position deviation occurs. At the −y direction end, a negative, being a reversed sign, position deviation occurs whose amount is the same as that of the positive position deviation. When performing multiple writing with a shift amount being half the width dimension of the stripe region 32, averaging is achieved by combining the position shift amount due to writing to the first stripe layer shown in FIG. 7A and the position shift amount due to writing to the second stripe layer shown in FIG. 7B. Therefore, as shown in FIG. 7C, the absolute value of the position shift amount can be reduced to ½. If quadruple (multiple) writing is performed while shifting the irradiation region in the y direction, the position shift amount can be reduced to ¼.

Thus, the averaging effect can be enhanced by increasing the number of times of multiple writing (multiplicity) which is performed while shifting the irradiation region in the y direction. However, simply increasing the number of passes of multiple writing leads to increasing the writing time because the times of moving the XY stage 105 increases. In order to prevent the writing time increase, the stage speed needs to be enhanced in proportion to the increase in the number of passes. Further, when the moving distance of the XY stage 105 increases, there is a possibility that the writing accuracy degrades due to a vibration increase along with the stage movement. Furthermore, deterioration of the stage mechanism is accelerated when the moving distance of the XY stage 105 increases, and thus, the maintenance cycle may become short. Then, according to the first embodiment, two or more stripe regions 32 and 37 are written during one movement of the XY stage 105. As a method for that, Y deflection of shifting, in the y direction, the irradiation region 34 of the multiple beams 20 is executed during performing writing in each stripe region 32. It will be specifically described.

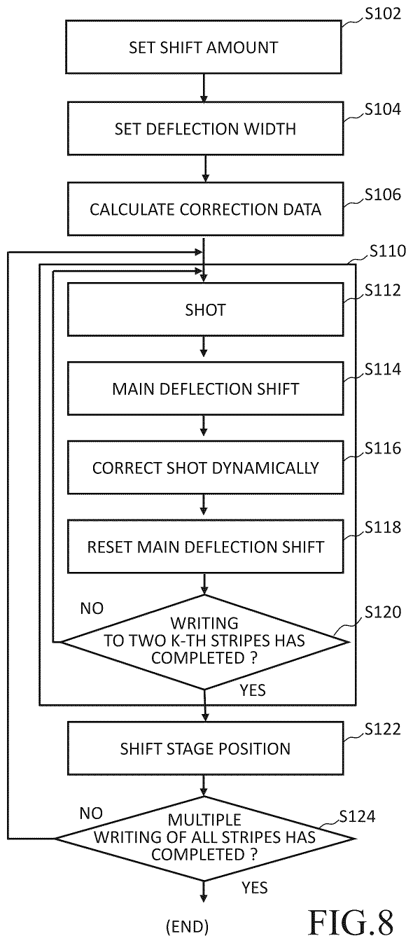

FIG. 8 is a flowchart showing an example of main steps of a writing method according to the first embodiment. In FIG. 8, the writing method of the first embodiment executes a series of steps: a shift amount setting step (S102), a deflection width setting step (S104), a correction data calculation step (S106), a two-stripe-regions writing step (S110), a stage position shift step (S122), and a determination step (S124).

As internal steps of the two-stripe-regions writing step (S110), a series of steps is performed: a shot step (S112), a main deflection shift (Y deflection) step (S114), a shot and dynamic correction step (S116), a main deflection shift reset (Y deflection reset) step (S118), and a determination step (S120).

In the shift amount setting step (S102), the shift amount setting unit 50 sets a shift (displacement) amount of the writing position in the y direction due to the stage movement. The shift amount of the stage in the y direction is set such that the multiplicity at each stripe region is equal to each other. Hereinafter, the case where the y-direction width of the stripe region 32 is regarded/defined as the shift amount will be described as an example.

In the deflection width setting step (S104), the deflection width setting unit 52 sets a deflection width (distance) of the irradiation region 34 which is deflected by Y deflection. According to the first embodiment, Y deflection of a larger deflection amount than the beam pitch is performed. The deflection width of the Y deflection is set to be a size different from the shift amount by the stage movement. It is preferable that the deflection width is set to be a size smaller than the shift amount of the stage movement. Preferably, the deflection width is set to be half the shift amount. Hereinafter, the case where the deflection width is set to be half the y-direction width of the stripe region 32 will be described as an example.

In the correction data calculation step (S106), the correction unit 71 calculates correction data for correcting a position deviation of the beam array due to the Y deflection.

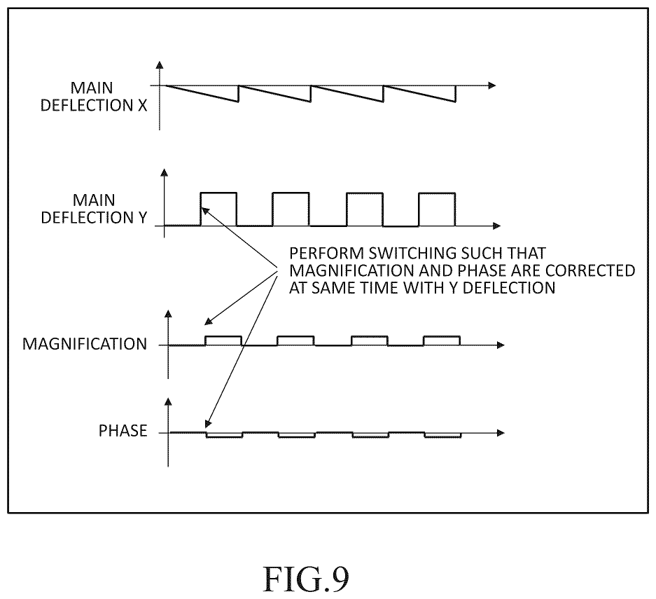

FIG. 9 is an illustration showing a time chart of a main deflection, magnification correction and phase correction, as an example of a writing sequence, according to the first embodiment. In FIG. 9, as main deflection X, tracking control is reset every four shots of the multiple beams 20, for example. According to the first embodiment, as main deflection Y, the irradiation region 34 of the multiple beams 20 is moved (shifted) in the y direction by beam deflection (Y deflection) during the tracking control.

The switching width of the deflection amount of Y deflection (deflection width of Y deflection) is set to be larger than the deflection width of beam deflection in tracking control. The deflection width of beam deflection in tracking control is set to be within the range in which no position deviation due to beam deflection of the multiple beams 20 occurs. Therefore, in beam deflection larger than the deflection width of beam deflection in tracking control, a position deviation of the multiple beams 20 resulting from the beam deflection may be generated. Since 2×4 multiple beams 20 are used for explanation in the example described later, the deflection width of beam deflection in tracking control is set to be two pixels being the same as the beam pitch. However, if the number of beams increases, such as the case of 32×32 multiple beams 20, the deflection width of beam deflection in tracking control is set to be eight times the beam pitch (eight beam pitches), for example. In the case where the deflection width of Y deflection exceeds the deflection width in tracking control, position deviation of the multiple beams 20 due to the beam deflection is easy to be generated. In the VSB writing using a single beam, the shot position itself can be corrected even when position deviation occurs because of an increased deflection amount. However, in the multiple beams 20, it is difficult to independently correct the shot position of each beam. Then, according to the first embodiment, in order to reduce the position deviation of the multiple beams 20 resulting from beam deflection as much as possible, the magnification and the phase of the beam array shape of the multiple beams 20 are corrected. In the first embodiment, both of the magnification and the phase of the beam array shape are corrected, however, it is not limited thereto. Either one of the magnification and the phase of the beam array shape may be corrected. Further, in the state where the beam deflection amount is large, if the writing apparatus is adjusted so that position deviation of multiple beams may be reduced, the position deviation of the multiple beams becomes increased when the amount of beam deflection is reduced. Also in this case, being the same as the first embodiment, it is possible to correct the magnification and the phase of the beam array shape of the multiple beams 20 in order to reduce position deviation of the multiple beams 20 as much as possible.

Before starting writing processing, it is necessary to measure, in advance by experiment and the like, a deviation of the beam array shape of the multiple beams 20 resulting from Y deflection, and a magnification and a phase of the beam array shape which are to be set for correcting the deviation. For example, by making the deflection width of Y deflection variable, a deviation of the beam array shape and an optimal magnification error and phase of the beam array shape for correcting the deviation are measured for each deflection width. The measured phase data and magnification data are stored in the storage device 140.

The correction unit 71 reads phase data and magnification data from the storage device 140, and calculates a phase correction amount and a magnification correction amount depending on a set deflection width. The calculated phase correction amount data and magnification correction amount data are output to the electrostatic lens control circuit 137 together with timing information on Y deflection. In the case of FIG. 9, at the timing of Y deflection, magnification correction and phase correction are started, and at the timing of resetting the Y deflection, the magnification correction and the phase correction are stopped. Alternatively, at the timing of changing the Y deflection amount, magnification correction and phase correction which are depending on the Y deflection amount may be set.

In the two-stripe-regions writing step (S110), first, the writing data processing unit 70 reads chip data (writing data) stored in the storage device 140, and generates irradiation time data for each pixel. The irradiation time data is rearranged in the order of shots in accordance with a preset writing sequence. The irradiation time data is stored in the storage device 142. The transmission processing unit 74 transmits the irradiation time data in the order of shots to the deflection control circuit 130. The writing mechanism 150 writes a pattern on the target object 101 with the multiple beams 20. The writing control unit 72 controls writing operations of the writing mechanism 150.

First, under the control of the writing control unit 72, the writing mechanism 150 performs writing with the multiple beams 20 to two or more stripe regions 32 and 37 in a plurality of stripe regions 32 and 37 aligned partially overlapping with each other in the y direction on the target object 101, during the movement of the XY stage 105 having the target object 101 thereon in the reverse direction to the writing movement direction, while repeatedly switching (changing) the irradiation region, in the y direction (first direction) being linearly independent with respect to the writing movement direction (x direction), by a deflection amount of the width larger than the beam pitch size of the multiple beams 20, and applying irradiation with the multiple beams 20 at each time of the switching of the irradiation region. Each of the stripe regions 32 and 37 is a rectangle whose y-direction width is equal to or less than the width size of the design irradiation region of the multiple beams 20, and x-direction (second direction) width orthogonal to the y direction is longer than the y-direction width size, wherein the width size of the design irradiation region of the multiple beams 20 is obtained by adding the beam pitch to the y-direction size of the beam array, in other words, by multiplying the number of y-direction beams (for example, 512 beams) by the beam pitch. That is, while performing, in the y-direction (first direction), beam deflection of a deflection amount larger than the beam pitch size of the multiple beams 20, the writing mechanism 150 writes, with the multiple beams 20, two or more stripe regions 32 and 37 in the plurality of stripe regions 32 and 37 aligned partially overlapping with each other in the y direction on the target object 101 during the movement of the XY stage 105 in the x or −x direction. The plurality of stripe regions 32 and 37 are aligned partially overlapping with each other in the y direction. As described above, each of the stripe regions 32 and 37 is a rectangle whose y-direction width is, for example, the width size of the design irradiation region 34 of the multiple beams 20, and x-direction width is longer than the y-direction width size. Specifically, the writing mechanism 150 operates as follows:

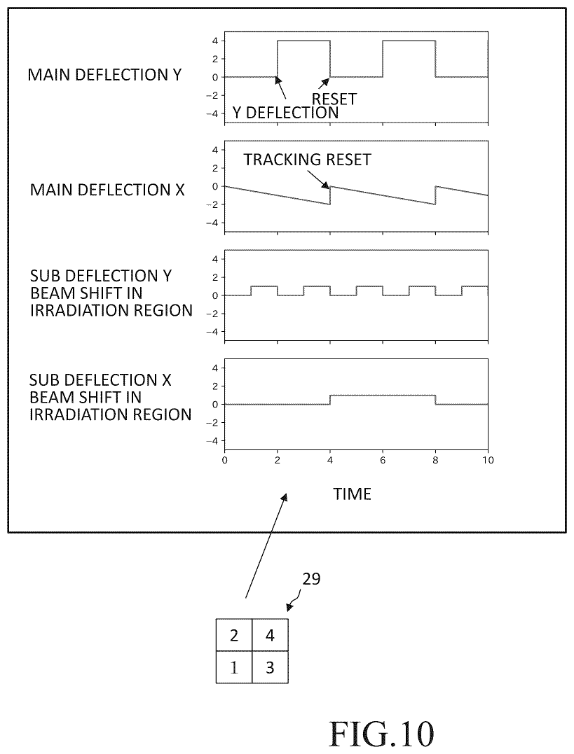

FIG. 10 is an illustration showing a time chart of a main deflection and a sub deflection, as an example of a writing sequence, according to the first embodiment.

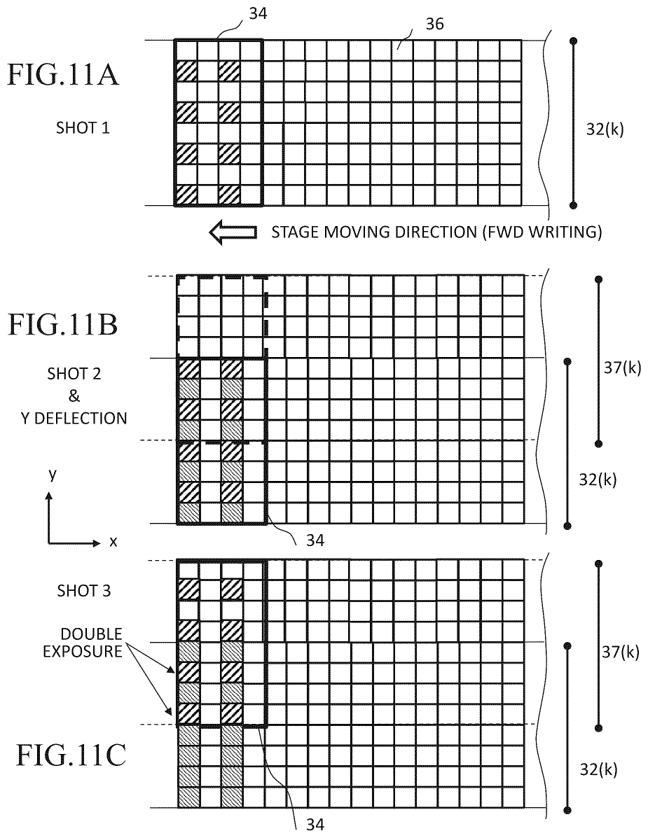

FIGS. 11A to 11C are illustrations each showing a part of an example of a writing sequence according to the first embodiment. In the case of FIGS. 11A to 11C, 2×4 multiple beams 20 are used. One sub-irradiation region 29 (pitch cell) is configured by a rectangular (including square) region surrounded by the size of x- and y-direction beam pitches of the multiple beams 20. In the examples of FIG. 10 and FIGS. 11A to 11C, each sub-irradiation region 29 is composed of 2×2 pixels, for example. According to the writing sequence used in the examples of FIG. 10 and FIGS. 11A to 11C, writing is performed in the order of the lower left, the upper left, the lower right, and the upper right inside the sub-irradiation region 29. FIG. 10 and FIGS. 11A to 11C show the case where the inside of each sub-irradiation region 29 is written by two different beams.

While writing is performed in each stripe region 32, the XY stage 105 is moved in the −x direction (or x direction). At least during an irradiation with the multiple beams 20, a tracking control is performed so that the irradiation region 34 of the multiple beams 20 may follow the movement of the XY stage 105. In other words, during writing each stripe region 32, a tracking control is performed so that the irradiation region 34 of the multiple beams 20 may follow the movement of the XY stage 105. Specifically, for example, while four pixels are written (exposed), in order that the relative position of the irradiation region 34 with respect to the target object 101 may not be shifted by the movement of the XY stage 105, the irradiation region 34 is made to follow the movement of the XY stage 105 by collective deflection of all of the multiple beams 20 in the x direction by the main deflector 208. In other words, a tracking control is performed. Each of the examples of FIGS. 11A to 11C shows a writing operation where the XY stage 105 continuously moves at the speed at which the XY stage 105 moves the distance of two pixels while the region (two pixels) of ½ (1/the number of beams used for irradiation) in each sub-irradiation region 29 in the first stripe layer, and the region (two pixels) of ½ (1/the number of beams used for irradiation) in each sub-irradiation region 29 in the second stripe layer are written.

The shot cycle is the total time of the maximum irradiation time of one beam shot and the settling time of the DAC amplifier of the deflector. As the tracking cycle which performs a tracking reset for every four pixel writing, the same time as that of four shot cycles can be used. The maximum irradiation time of one beam shot is set in advance. For example, the irradiation time that is the maximum in all the shots in the writing processing including dose modulation, etc. can be set as the maximum irradiation time.

The tracking control is controlled by an x-direction deflection (main deflection X) by the main deflector 208, for example. After one tracking cycle is completed, the tracking is reset to return to the last tracking starting position. In the examples of FIG. 10 and FIGS. 11A to 11C, as the main deflection X, the tracking control is reset every four shots of the multiple beams 20. Shifting of the irradiation position of the multiple beams 20 in the irradiation region 34 is controlled by a combination of an x-direction deflection (sub deflection X) and a y-direction deflection (sub deflection Y) by the sub deflector 209.

Under the control of the writing control unit 72, while performing writing in each stripe region 32 in the first stripe layer, the writing mechanism 150 further performs writing in each stripe region 37 in the second stripe layer by moving the irradiation region 34 of the multiple beams 20 in the y direction by beam deflection. The beam deflection from the first stripe layer to the second stripe layer is performed during a tracking control. In the examples of FIG. 10 and FIGS. 11A to 11C, switching between the first stripe layer and the second stripe layer is performed for every two shots in four shots in the tracking control.

In the shot step (S112), a shot with the multiple beams 20 to the first stripe layer is performed.

Specifically, it operates as follows:

First, in FIG. 11A, as the shot 1, while a tracking control is performed by main deflection X, each beam irradiates the lower left pixel in the sub-irradiation region 29 concerned in the k-th stripe region 32 of the first stripe layer in the irradiation region 34 of the multiple beams 20. At the time when the maximum irradiation time of the shot 1 has passed, the sub deflector 209 provides deflection such that the beam writing position is adjusted (shifted) to write the upper left pixel which has not yet been written in each sub-irradiation region 29.

Then, in FIG. 11B, as the shot 2, while a tracking control is performed by main deflection X, each beam irradiates the upper left pixel in the sub-irradiation region 29 concerned in the k-th stripe region 32 of the first stripe layer in the irradiation region 34 of the multiple beams 20.

In the main deflection shift (Y deflection) step (S114), at the time when the maximum irradiation time of the shot 2 has passed, the main deflector 208 deflects the multiple beams 20 in the y direction by a deflection amount larger the beam pitch size of the multiple beams 20. Specifically, the main deflector 208 provides deflection (Y deflection: main deflection Y) such that the irradiation region 34 of the multiple beams 20 is shifted in the y direction by a set deflection width. In the example of FIG. 11B, the irradiation region 34 of the multiple beams 20 is shifted in the y direction by a deflection width being the size of four pixels (½ of the stripe region width). Thereby, the target, as the irradiation region 34, is switched (changed) from the k-th stripe region 32 in the first stripe layer to the k-th stripe region 37 in the second stripe layer.

In the shot and dynamic correction step (S116), in the state where the irradiation region 34 of the multiple beams 20 has been deflected in the y direction by a deflection width by Y deflection, shot with the multiple beams 20 is performed to the second stripe layer. Specifically, it operates as follows:

As shown in FIG. 11C, as the shot 3, while a tracking control is performed by main deflection X, each beam irradiates the lower left pixel in the sub-irradiation region 29 concerned in the k-th stripe region 37 of the second stripe layer in the irradiation region 34 of the multiple beams 20. Thereby, the second irradiation is performed to the lower left pixel in the sub-irradiation region 29 concerned in the upper half region of the k-th stripe region 37 in the first stripe layer. Thus, double (multiple) writing is carried out.

Then, under the control of the electrostatic lens control circuit 137, the electrostatic lenses 212 and 214 (correction unit) correct a position deviation of the beam array, resulting from Y deflection, with respect to the shot of the multiple beams 20 performed in the state of being Y-deflected. In other words, the electrostatic lenses 212 and 214 (correction unit) correct a position deviation of the beam array, occurring depending on the amount of beam deflection in y direction, with respect to the shot of the multiple beams 20 performed while switching (changing) the irradiation region 34. Specifically, using the two electrostatic lenses 212 and 214, phase deviation and magnification deviation of the beam array shape of the multiple beams 20 are corrected. Since the number of correction targets is two, two or more electrostatic lenses 212 and 214 are sufficient. The shot of the multiple beams 20 performed in the state of being Y-deflected is corrected dynamically. According to the time chart shown in FIG. 9, at the timing of Y deflection, the electrostatic lens control circuit 137 controls the electrostatic lenses 212 and 214 to correct phase deviation and magnification deviation. Then, at the timing of resetting the Y deflection, the electrostatic lens control circuit 137 controls the electrostatic lenses 212 and 214 to stop the correction of the phase deviation and the magnification deviation. The correction of the phase deviation is performed depending on a calculated phase correction amount. The correction of the magnification deviation is performed depending on a calculated magnification correction amount.

Thereby, even in the case where Y deflection is performed by a deflection width larger than the beam deflection width of tracking control, position deviation resulting from the Y deflection can be prevented or reduced.

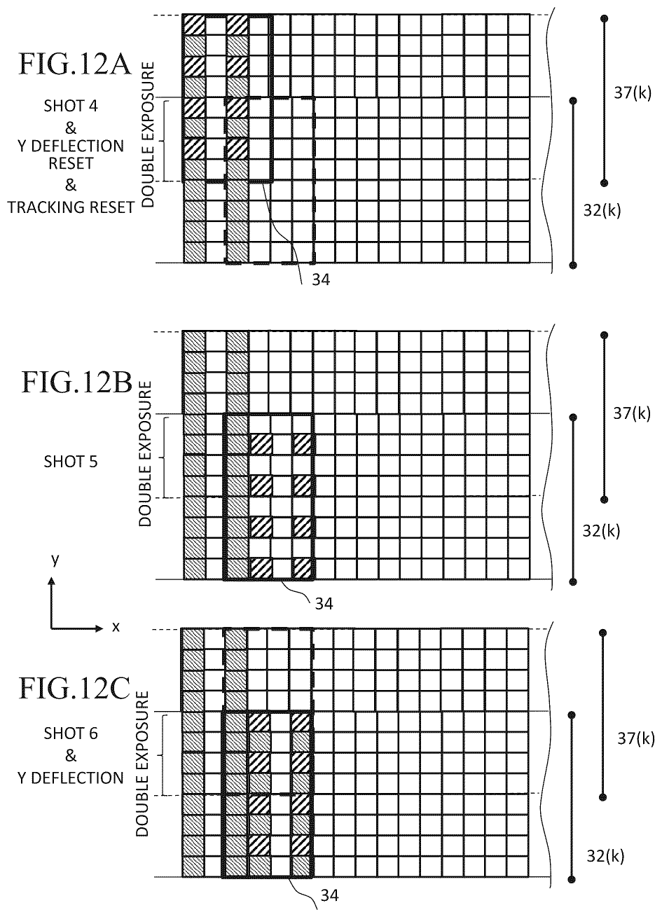

FIGS. 12A to 12C are illustrations each showing another part of an example of a writing sequence according to the first embodiment. FIGS. 12A to 12C show the states of shots 4 to 6.

In FIG. 12A, as the shot 4, while a tracking control is performed by main deflection X, each beam irradiates the upper left pixel in the sub-irradiation region 29 concerned in the k-th stripe region 37 of the second stripe layer in the irradiation region 34 of the multiple beams 20. Thereby, the second irradiation is performed to the upper left pixel in the sub-irradiation region 29 concerned in the upper half region of the k-th stripe region 37 in the first stripe layer. Thus, double (multiple) writing is carried out. Further, since the shot 4 is in the state of having been Y-deflected, position deviation of the beam array resulting from the Y deflection is corrected similarly to the shot 3.

At the time when the maximum irradiation time of the shot 4 has passed, the tracking control is reset. During the tracking cycle of the shot 4, the XY stage 105 has moved the distance of two pixels. Therefore, the irradiation region 34 moves in the x direction by two pixels by the tracking reset.

In the main deflection shift reset (Y deflection reset) step (S118), after the shot 4, resetting (Y deflection reset) is performed for the state where the irradiation region 34 of the multiple beams 20 has been deflected in the y direction by a deflection width by Y deflection. The main deflector 208 provides deflection, by resetting the Y deflection, such that the irradiation region 34 of the multiple beams 20 is shifted in the −y direction by a deflection width.

Writing to the lower left pixel in each sub-irradiation region 29 concerned in the k-th stripe region 37 in the first stripe layer has already been finished in the shot 1. Therefore, after the tracking reset, firstly in the next tracking cycle, the sub deflector 209 provides deflection such that the beam writing position is adjusted (shifted) to write the lower right pixel which has not yet been written in each sub-irradiation region 29.

In the determination step (S120), the writing control unit 72 determines whether writing two stripe regions of the k-th stripe region 32 in the first stripe layer and the k-th stripe region 37 in the second stripe layer has been completed. When completed, it goes to the stage position shift step (S122). When not completed, it returns to the shot step (S112), and repeats the steps from the shot step (S112) to the determination step (S120) until writing to the two stripe regions of the k-th stripe region 32 in the first stripe layer and the k-th stripe region 37 in the second stripe layer is completed. In the state of FIG. 12A, since writing of the two stripe regions of the k-th stripe region 32 in the first stripe layer and the k-th stripe region 37 in the second stripe layer has not yet been completed, the steps from the shot step (S112) to the determination step (S120) are repeated as explained below.

In FIG. 12B, as the shot 5, while a tracking control is performed by main deflection X, each beam irradiates the lower right pixel in the sub-irradiation region 29 concerned in the k-th stripe region 32 in the first stripe layer in the irradiation region 34 of the multiple beams 20. At the time when the maximum irradiation time of the shot 5 has passed, the sub deflector 209 provides deflection such that the beam writing position is adjusted (shifted) to write the upper right pixel which has not yet been written in each sub-irradiation region 29.

Next, in FIG. 12C, as the shot 6, while a tracking control is performed by main deflection X, each beam irradiates the upper right pixel in the sub-irradiation region 29 concerned in the k-th stripe region 32 of the first stripe layer in the irradiation region 34 of the multiple beams 20.

In the main deflection shift (Y deflection) step (S114), at the time when the maximum irradiation time of the shot 6 has passed, the main deflector 208 deflects the multiple beams 20 in the y direction by a deflection amount larger the beam pitch size of the multiple beams 20.

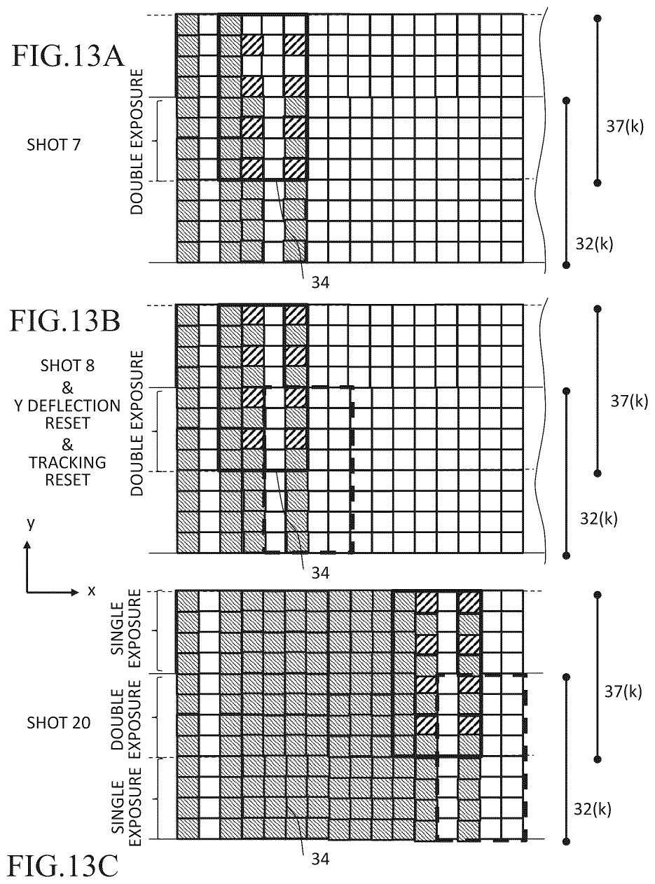

FIGS. 13A to 13C are illustrations each showing another part of an example of a writing sequence according to the first embodiment. FIGS. 13A to 13C show the states of shots 7, 8, and 20.

In FIG. 13A, as the shot 7, while a tracking control is performed by main deflection X, each beam irradiates the lower right pixel in the sub-irradiation region 29 concerned in the k-th stripe region 37 of the second stripe layer in the irradiation region 34 of the multiple beams 20. Thereby, the second irradiation is performed to the lower right pixel in the sub-irradiation region 29 concerned in the upper half region of the k-th stripe region 37 in the first stripe layer. Thus, double (multiple) writing is carried out.

Further, since the shot 7 is in the state of having been Y-deflected, position deviation of the beam array due to the Y deflection is corrected, similarly to the shot 3, using the two electrostatic lenses 212 and 214.

In FIG. 13B, as the shot 8, while a tracking control is performed by main deflection X, each beam irradiates the upper right pixel in the sub-irradiation region 29 concerned in the k-th stripe region 37 of the second stripe layer in the irradiation region 34 of the multiple beams 20. Thereby, the second irradiation is performed to the upper right pixel in the sub-irradiation region 29 concerned in the upper half region of the k-th stripe region 37 in the first stripe layer. Thus, double (multiple) writing is carried out. Further, since the shot 8 is in the state of having been Y-deflected, position deviation of the beam array due to the Y deflection is corrected similarly to the shot 4.

At the time when the maximum irradiation time of the shot 8 has passed, the tracking control is reset. During the tracking cycle of the shot 8, the XY stage 105 has moved the distance of two pixels. Therefore, the irradiation region 34 moves in the x direction by two pixels by the tracking reset.

In the main deflection shift reset (Y deflection reset) step (S118), after the shot 8, resetting (Y deflection reset) is performed for the state where the irradiation region 34 of the multiple beams 20 has been deflected in the y direction by a deflection width by Y deflection. The main deflector 208 provides deflection, by resetting the Y deflection, such that the irradiation region 34 of the multiple beams 20 is shifted in the −y direction by a deflection width.

Writing of the lower right pixel in each sub-irradiation region 29 concerned in the k-th stripe region 37 in the first stripe layer has already been finished in the shot 5. Therefore, after the tracking reset, firstly in the next tracking cycle, the sub deflector 209 provides deflection such that the beam writing position is adjusted (shifted) to write the lower left pixel which has not yet been written in each sub-irradiation region 29. In other words, the sub deflection in the x direction is released (cancelled).

By repeating the operation of the shots 1 to 8, as shown in FIG. 13C, writing processing proceeds with respect to the two stripe regions of the k-th stripe region 32 in the first stripe layer and the k-th stripe region 37 in the second stripe layer. By writing to the two or more stripe regions 32 and 37 performed during the movement of the XY stage 105, a part of the two or more stripe regions 32 and 37 is multiply written. In the example of FIG. 13C, double (multiple) writing is carried out at the part where the k-th stripe region 32 in the first stripe layer and the k-th stripe region 37 in the second stripe layer are overlapped with each other, whereas single writing is performed at the part where no region is overlapped.

In the stage position shift step (S122), after writing to the above-described two or more stripe regions 32 and 37 during the movement of the XY stage 105, the stage control mechanism 138, controlled by the writing control unit 72, shifts the position to two or more stripe regions to be next written. In this process, the XY stage 105 is shifted in the y direction so that a part of the stripe regions 32 and 37, which is to be next written, may be overlapped with another part of the two or more stripe regions 32 and 37, which has already been written. The shift amount L by which the XY stage 105 is shifted in the y direction is set such that the multiplicity at each position is equal to each other. Here, the y-direction width of the stripe region 32 is defined as the shift amount. Therefore, here, the XY stage 105 is moved in order that the irradiation region 34 of the multiple beams 20 may be located at the (k+1)th stripe region 32 in the first stripe layer which has been shifted in the y direction by a preset shift amount from the k-th stripe region 32 in the first stripe layer.

In the determination step (S124), the writing control unit 72 determines whether multiple writing to all the stripe regions 32 has been completed. If there remained stripe regions 32 and 37 in which multiple writing has not yet been performed, it returns to the two-stripe-regions writing step (S110), and repeats each step from the two-stripe-regions writing step (S110) to the determination step (S124) until multiple writing to all the stripe regions 32 and 37 has been completed. After the position of the XY stage 105 is shifted, by performing writing to the next two or more stripe regions, the part (single-written part) where two or more stripe regions 32 and 37 having been written overlap with the next two or more stripe regions is multiply written.

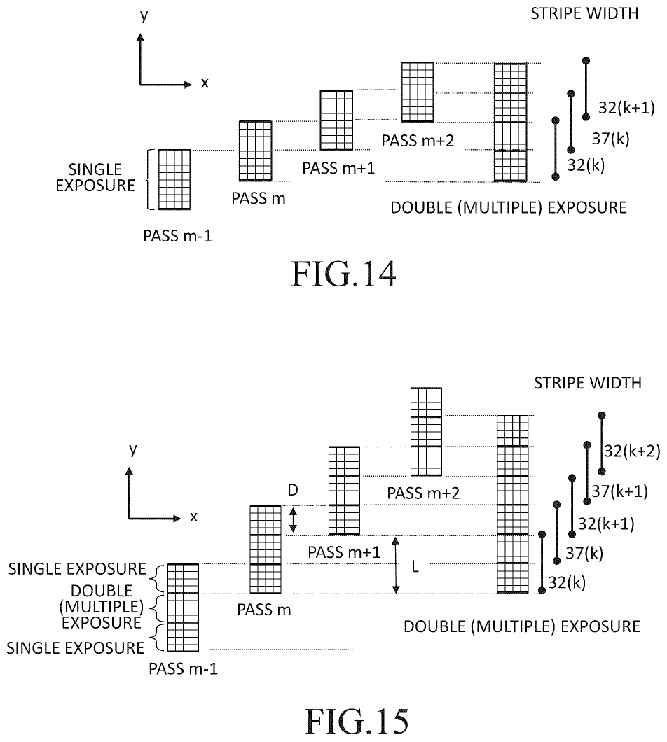

FIG. 14 is an illustration describing a method of multiple writing according to a comparative example 1 of the first embodiment 1. In FIG. 14, the comparative example shows the case where no Y deflection is performed. In the case of not performing Y deflection, writing is performed to the stripe region one by one during movement in the x direction of the XY stage 105. Therefore, for example, in order to carry out double (multiple) writing, after the k-th stripe region 32 in the first stripe layer has been written, the writing position is shifted in the y direction by half the y-direction width of the stripe region by moving the XY stage 105. Then, the k-th stripe region 37 in the second stripe layer is written. Thus, for each one stage movement (one pass), the writing position is shifted in the y direction by half the y-direction width of the stripe region by moving the XY stage 105. Thereby, double (multiple) writing at each position can be carried out.

FIG. 15 is an illustration describing a method of multiple writing according to an example of a writing sequence of the first embodiment. In FIG. 15, Y deflection is performed according to the first embodiment. Writing is performed to each two stripe regions during movement in the x direction of the XY stage 105. The two stripe regions 32 and 37 are overlapped with each other by halves in the y direction. Therefore, double (multiple) writing has been performed to the upper half region of the k-th stripe region 32 in the first stripe layer (the lower half region of the k-th stripe region 37 in the second stripe layer). The lower half region of the k-th stripe region 32 in the first stripe layer and the upper half region of the k-th stripe region 32 in the second stripe layer are in a single written state. Therefore, for each one stage movement (one pass), the writing position is shifted in the y direction by a shift amount L being the same as the y-direction width of the stripe region by moving the XY stage 105. Thus, the shift amount L by which the XY stage 105 is shifted in the y direction is set such that the multiplicity at each position is equal to each other. Thereby, the lower half region of the k-th stripe region 32 in the first stripe layer becomes in a double (multiple) written state by being combined with the upper half region of the (k−1)th stripe region 32 in the second stripe layer. The upper half region of the k-th stripe region 32 in the first stripe layer (the lower half region of the k-th stripe region 37 in the second stripe layer) is doubly (multiply) written. The upper half region of the k-th stripe region 32 in the second stripe layer becomes in a double (multiple) written state by being combined with the lower half region of the (k+1)th stripe region 32 in the first stripe layer. By repeating this operation, multiple writing to each of the stripe region 32 and 37 can be performed.

According to the first embodiment, since the stage speed is half that of the comparative example, the time taken for one stage movement (one pass) is twice that of it. However, in the first embodiment, the shift amount in the y direction can be made twice that of the comparative example. Further, the number of times of adjustment of the writing starting position, in accordance with the y-direction movement between stripes of the XY stage 105, can be made half of it. Therefore, the adjustment time can be reduced. Accordingly, the writing time can be finally equivalent to or shorter than the case where no y-direction shift is performed.

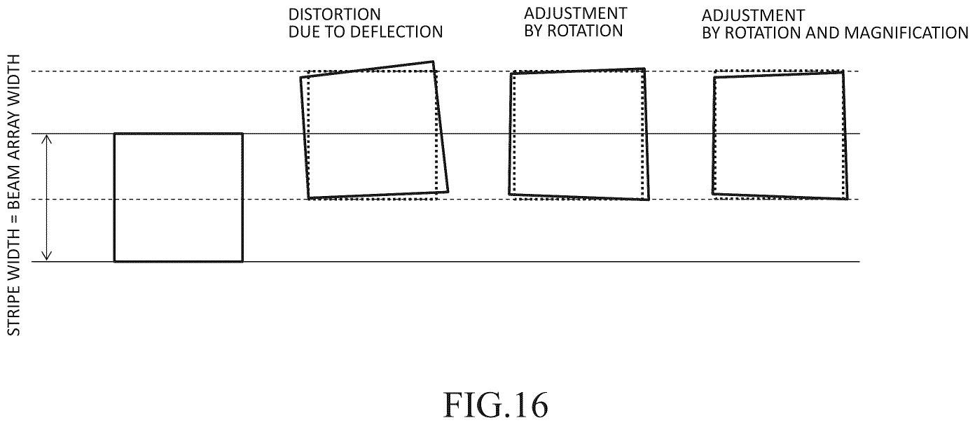

FIG. 16 is an illustration describing a distortion resulting from Y deflection and a distortion correction according to the first embodiment. In the Y deflection as described above, the irradiation region 34 of the multiple beams 20 is deflected by a deflection width being half of the y-direction width of the stripe region 32. Consequently, distortion due to the deflection occurs in the beam array shape. For coping with this, according to the first embodiment, phase deviation correction and magnification deviation correction are performed. By performing the phase deviation correction using rotation, distortion can be reduced. By dynamically performing phase deviation correction using rotation, and magnification correction, distortion can be further reduced.

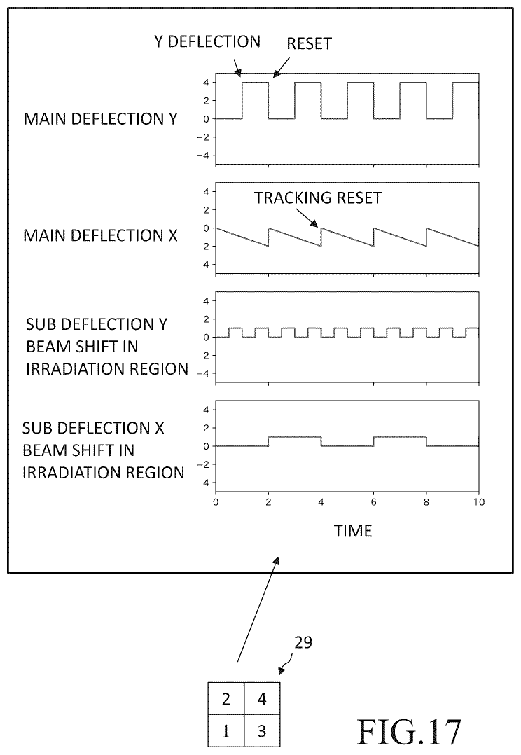

FIG. 17 is an illustration showing a time chart of a main deflection and a sub deflection, as another example of a writing sequence, according to the first embodiment.

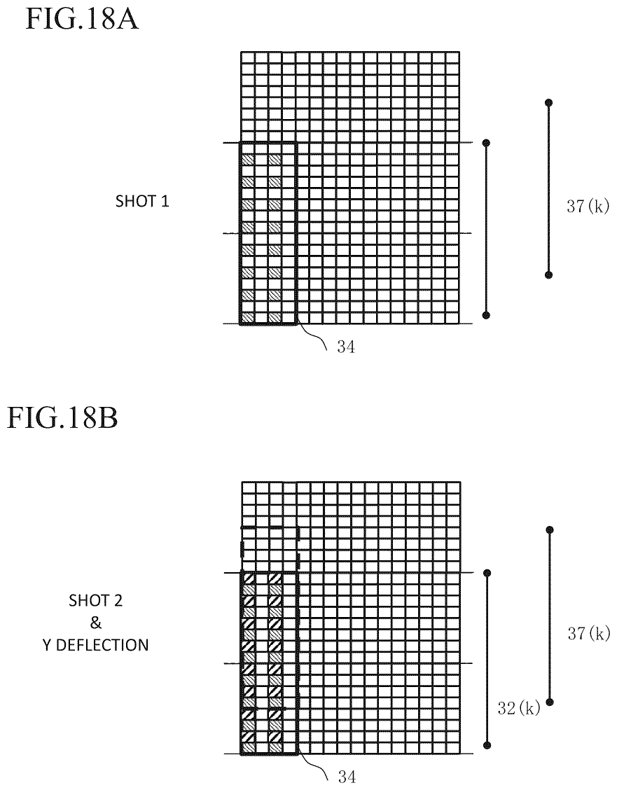

FIGS. 18A and 18B are illustrations each showing a part of another example of a writing sequence according to the first embodiment. In the case of FIGS. 18A and 18B, 2×8 multiple beams 20 are used. Further, one sub-irradiation region 29 (pitch cell) is configured by a rectangular region surrounded with the sizes of x- and y-direction beam pitches of the multiple beams 20. In the examples of FIG. 17 and FIGS. 18A and 18B, each sub-irradiation region 29 is composed of 2×2 pixels, for example. According to the writing sequence used in the examples of FIG. 17 and FIGS. 18A and 18B, writing is performed in the order of the lower left, the upper left, the lower right, and the upper right inside the sub-irradiation region 29. FIG. 17 and FIGS. 18A and 18B show the case where the inside of each sub-irradiation region 29 is written with two different beams.

In the examples of FIG. 17 and FIGS. 18A and 18B, the shift amount setting unit 50 sets a shift amount of the writing position in the y direction due to the movement of the stage. Hereinafter, the case of setting the shift amount to be half the y-direction width of the stripe region 32 is described as an example. Further, the deflection width setting unit 52 sets a deflection width (distance) of the irradiation region 34 which is to be deflected by Y deflection. In the first embodiment, Y deflection whose deflection amount is larger than the beam pitch is performed. Preferably, the deflection width is set to be half the shift amount. Here, the case of setting the deflection width to be one fourth the dimension of the y-direction width of the stripe region 32 is described as an example. The examples of FIG. 17 and FIGS. 18A and 18B explain the case of performing quadruple (multiple) writing. Therefore, stripe layers from the first stripe layer to the fourth stripe layer are generated. Each stripe layer is shifted each other in the y direction by the dimension of one fourth of the y-direction width of the stripe region 32.

In the correction data calculation step (S106), the correction unit 71 calculates correction data for correcting a position deviation of the beam array occurring due to Y deflection. Here, correction data in the case of performing deflection by a deflection width being one fourth of the y-direction width of the stripe region 32 is calculated, i.e., the magnification and rotation amount of the beam array by which distortion of the beam array shape, due to the one fourth deflection amount, can be best cancelled (corrected) are calculated. Since the number of beams in the y direction has become twice, that is to eight from four, if the pixel size is the same as that of the case of the number of beams in the y direction being four, the y-direction width of the stripe region 32 in the first stripe layer becomes twice. Similarly, the y-direction width of the stripe region 37 in the second stripe layer also becomes twice.

While writing is performed in each stripe region 32, the XY stage 105 is moved in the −x direction (or x direction). Then, during the writing in each stripe region 32, a tracking control is performed so that the irradiation region 34 of the multiple beams 20 may follow the movement of the XY stage 105. Each of the examples of FIGS. 18A and 18B shows a writing operation where the XY stage 105 continuously moves at the speed at which the XY stage 105 moves the distance of two pixels while a ½ (1/the number of beams used for irradiation) region (two pixels) in each sub-irradiation region 29 in the first stripe layer, and a ½ (1/the number of beams used for irradiation) region (two pixels) in each sub-irradiation region 29 in the second stripe layer are written.

Then, under the control of the writing control unit 72, while performing writing in each stripe region 32 in the first stripe layer, the writing mechanism 150 further performs writing in each stripe region 37 in the second stripe layer by moving the irradiation region 34 of the multiple beams 20 in the y direction by beam deflection. The beam deflection from the first stripe layer to the second stripe layer is performed during a tracking control. In the examples of FIG. 17 and FIGS. 18A and 18B, switching between the first stripe layer and the second stripe layer is performed for every two shots in four shots in the tracking control.

First, in FIG. 18A, as the shot 1, while a tracking control is performed by main deflection X, each beam irradiates the lower left pixel in the sub-irradiation region 29 concerned in the k-th stripe region 32 of the first stripe layer in the irradiation region 34 of the multiple beams 20. At the time when the maximum irradiation time of the shot 1 has passed, the sub deflector 209 provides deflection such that the beam writing position is adjusted (shifted) to write the upper left pixel which has not yet been written in each sub-irradiation region 29.

Then, in FIG. 18B, as the shot 2, while a tracking control is performed by main deflection X, each beam irradiates the upper left pixel in the sub-irradiation region 29 concerned in the k-th stripe region 32 of the first stripe layer in the irradiation region 34 of the multiple beams 20.

In the main deflection shift (Y deflection) step (S114), at the time when the maximum irradiation time of the shot 2 has passed, the main deflector 208 deflects the multiple beams 20 in the y direction by a deflection amount larger the beam pitch size of the multiple beams 20. Specifically, the main deflector 208 provides deflection (Y deflection: main deflection Y) such that the irradiation region 34 of the multiple beams 20 is shifted in the y direction by a set deflection width. In the example of FIG. 18B, the irradiation region 34 of the multiple beams 20 is shifted in the y direction by a deflection width being the size of four pixels (¼ of the stripe region width). Thereby, the target, as the irradiation region 34, is switched from the k-th stripe region 32 in the first stripe layer to the k-th stripe region 37 in the second stripe layer.

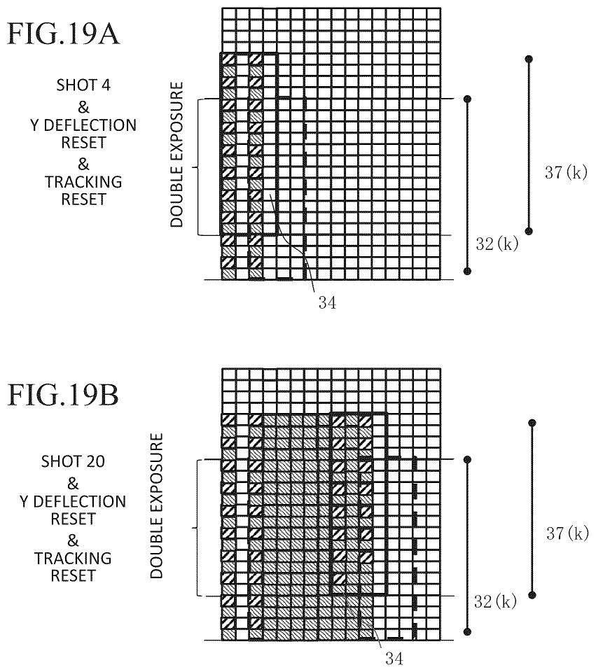

FIGS. 19A and 19B are illustrations each showing a part of another example of a writing sequence according to the first embodiment. FIG. 19A shows a state of shot 4, and FIG. 19B shows that of shot 20.

In the shot and dynamic correction step (S116), in the state where the irradiation region 34 of the multiple beams 20 has been deflected in the y direction by a deflection width by Y deflection, shot with the multiple beams 20 is performed to the second stripe layer. Specifically, it operates as follows:

As the shot 3 not shown in the figure, while a tracking control is performed by main deflection X, each beam irradiates the lower left pixel in the sub-irradiation region 29 concerned in the k-th stripe region 37 of the second stripe layer in the irradiation region 34 of the multiple beams 20. Thereby, the second irradiation is performed to the lower left pixel in the sub-irradiation region 29 concerned in the upper three-fourths region of the k-th stripe region 37 in the first stripe layer. Thus, double (multiple) writing is carried out.

Then, under the control of the electrostatic lens control circuit 137, the electrostatic lenses 212 and 214 (correction unit) correct a position deviation of the beam array, resulting from Y deflection, with respect to the shot of the multiple beams 20 performed in the state of being Y-deflected. Specifically, using the two electrostatic lenses 212 and 214, phase deviation and magnification deviation of the beam array shape of the multiple beams 20 are corrected.

Thereby, even in the case where Y deflection is performed by a deflection width larger than the beam deflection width of tracking control, position deviation resulting from the Y deflection can be prevented or reduced.

In FIG. 19A, as the shot 4, while a tracking control is performed by main deflection X, each beam irradiates the upper left pixel in the sub-irradiation region 29 concerned in the k-th stripe region 37 of the second stripe layer in the irradiation region 34 of the multiple beams 20. Thereby, the second irradiation is performed to the upper left pixel in the sub-irradiation region 29 concerned in the upper three-fourths region of the k-th stripe region 37 in the first stripe layer. Thus, double (multiple) writing is carried out. Further, since the shot 4 is in the state of having been Y-deflected, position deviation of the beam array resulting from the Y deflection is corrected similarly to the shot 3.

At the time when the maximum irradiation time of the shot 4 has passed, the tracking control is reset. During the tracking cycle of the shot 4, the XY stage 105 has moved the distance of two pixels. Therefore, the irradiation region 34 moves in the x direction by two pixels by the tracking reset.

In the main deflection shift reset (Y deflection reset) step (S118), after the shot 4, resetting (Y deflection reset) is performed for the state where the irradiation region 34 of the multiple beams 20 has been deflected in the y direction by a deflection width by Y deflection. The main deflector 208 provides deflection, by resetting the Y deflection, such that the irradiation region 34 of the multiple beams 20 is shifted in the −y direction by a deflection width.

Writing to the lower left pixel in each sub-irradiation region 29 concerned in the k-th stripe region 32 in the first stripe layer has already been finished in the shot 1. Therefore, after the tracking reset, firstly in the next tracking cycle, the sub deflector 209 provides deflection such that the beam writing position is adjusted (shifted) to write the lower right pixel which has not yet been written in each sub-irradiation region 29.

Then, the shot 5 irradiates the lower right pixel in the sub-irradiation region 29 concerned in the k-th stripe region 32 of the first stripe layer in the irradiation region 34 of the multiple beams 20. The shot 6 irradiates the upper right pixel in the sub-irradiation region 29 concerned in the k-th stripe region 32 of the first stripe layer in the irradiation region 34 of the multiple beams 20.

At the time when the maximum irradiation time of the shot 6 has passed, the main deflector 208 shifts the multiple beams 20 such that the irradiation region 34 of the multiple beams 20 is shifted in the y direction by a deflection width being the size of four pixels (¼ of the stripe region width). Thereby, the target, as the irradiation region 34, is switched from the k-th stripe region 32 in the first stripe layer to the k-th stripe region 37 in the second stripe layer.

Then, the shot 7 irradiates the lower right pixel in the sub-irradiation region 29 concerned in the k-th stripe region 37 of the second stripe layer in the irradiation region 34 of the multiple beams 20. The shot 8 irradiates the upper right pixel in the sub-irradiation region 29 concerned in the k-th stripe region 37 of the second stripe layer in the irradiation region 34 of the multiple beams 20. Since the shots 7 and 8 are in the state of having been Y-deflected, position deviation of the beam array resulting from the Y deflection is corrected similarly to the shots 3 and 4.

At the time when the maximum irradiation time of the shot 8 has passed, the tracking control is reset. During the tracking cycle of the shot 8, the XY stage 105 has moved the distance of two pixels. Therefore, the irradiation region 34 moves in the x direction by two pixels by the tracking reset.

In the main deflection shift reset (Y deflection reset) step (S118), after the shot 8, resetting (Y deflection reset) is performed for the state where the irradiation region 34 of the multiple beams 20 has been deflected in the y direction by a deflection width by Y deflection. The main deflector 208 provides deflection, by resetting the Y deflection, such that the irradiation region 34 of the multiple beams 20 is shifted in the −y direction by a deflection width.

Writing to the lower right pixel in each sub-irradiation region 29 concerned in the k-th stripe region 32 in the first stripe layer has already been finished in the shot 5. Therefore, after the tracking reset, firstly in the next tracking cycle, the sub deflector 209 provides deflection such that the beam writing position is adjusted (shifted) to write the lower left pixel which has not yet been written in each sub-irradiation region 29. In other words, the sub deflection in the x direction is released (canceled)

By repeating the operation of the shots 1 to 8, as shown in FIG. 19B, writing processing proceeds with respect to the two stripe regions of the k-th stripe region 32 in the first stripe layer and the k-th stripe region 37 in the second stripe layer. By writing to the two or more stripe regions 32 and 37 performed during the movement of the XY stage 105, a part of the two or more stripe regions 32 and 37 is multiply written. In the example of FIG. 19B, double (multiple) writing is carried out at the part where the k-th stripe region 32 in the first stripe layer and the k-th stripe region 37 in the second stripe layer are overlapped with each other, whereas single writing is performed at the part where no region is overlapped.

In the stage position shift step (S122), after writing to the above-described two or more stripe regions 32 and 37 during the movement of the XY stage 105, the stage control mechanism 138, controlled by the writing control unit 72, shifts the position to two or more stripe regions to be next written. In this process, the XY stage 105 is shifted in the y direction so that a part of the stripe regions 32 and 37, which is to be next written, may be overlapped with another part of the two or more stripe regions 32 and 37, which has already been written. The shift amount L by which the XY stage 105 is shifted in the y direction is set such that the multiplicity at each position is equal to each other. Here, a half of the y-direction width of the stripe region 32 is defined as the shift amount. Therefore, here, the XY stage 105 is moved in order that the irradiation region 34 of the multiple beams 20 may be located at the k-th stripe region in the third stripe layer which has been shifted in the y direction by a preset shift amount from the k-th stripe region 32 in the first stripe layer.

In the determination step (S124), the writing control unit 72 determines whether multiple writing to all the stripe regions 32 has been completed. If there remained stripe regions 32 and 37 in which multiple writing has not yet been performed, it returns to the two-stripe-regions writing step (S110), and repeats each step from the two-stripe-regions writing step (S110) to the determination step (S124) until multiple writing to all the stripe regions 32 and 37 has been completed.

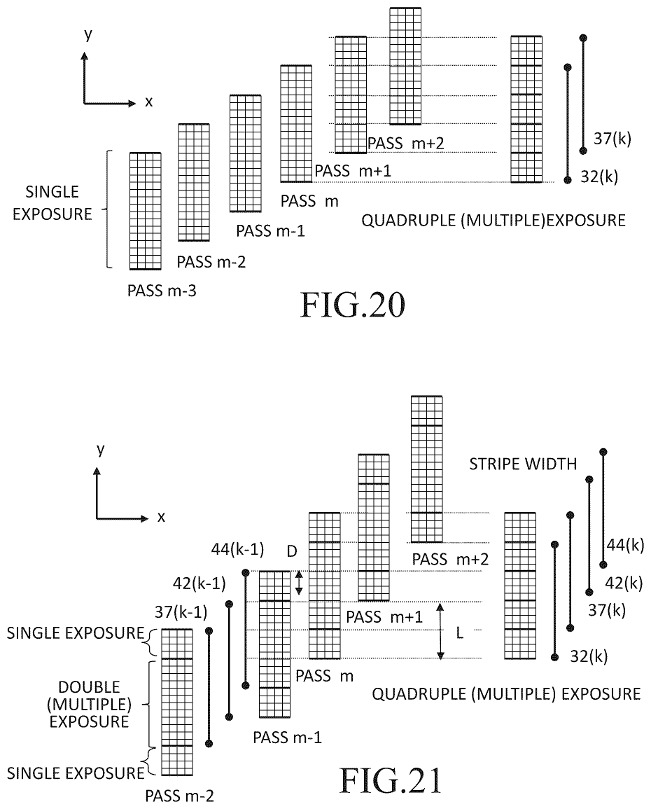

FIG. 20 is an illustration describing a method of multiple writing according to a comparative example 2 of the first embodiment. In FIG. 20, the comparative example shows the case where no Y deflection is performed. In the case of not performing Y deflection, writing is performed to the stripe region one by one during movement in the x direction of the XY stage 105. Therefore, for example, in order to carry out quadruple (multiple) writing, after the k-th stripe region 32 in the first stripe layer has been written, the writing position is shifted in the y direction by a quarter of the y-direction width of the stripe region by moving the XY stage 105. Then, the k-th stripe region 37 in the second stripe layer is written. Next, after the k-th stripe region 37 in the second stripe layer has been written, the writing position is shifted in the y direction by a quarter of the y-direction width of the stripe region by moving the XY stage 105. Then, the k-th stripe region in the third stripe layer is written. Next, after the k-th stripe region in the third stripe layer has been written, the writing position is shifted in the y direction by a quarter of the y-direction width of the stripe region by moving the XY stage 105. Then, the k-th stripe region in the fourth stripe layer is written. Thus, for each one stage movement (one pass), the writing position is shifted in the y direction by a quarter of the y-direction width of the stripe region by moving the XY stage 105. Thereby, quadruple (multiple) writing at each position can be carried out.

FIG. 21 is an illustration describing a method of multiple writing according to another example of a writing sequence of the first embodiment. In FIG. 21, Y deflection is performed according to the first embodiment. Writing is performed to each two stripe regions during movement in the x direction of the XY stage 105. The two stripe regions 32 and 37 are overlapped with each other by three-fourths in the y direction. Therefore, double (multiple) writing has been performed to the upper three-fourths region of the k-th stripe region 32 in the first stripe layer (the lower three-fourths region of the k-th stripe region 37 in the second stripe layer). The lower one-fourth region of the k-th stripe region 32 in the first stripe layer and the upper one-fourth region of the k-th stripe region 32 in the second stripe layer are in a single written state. Accordingly, for each one stage movement (one pass), the writing position is shifted in the y direction by a shift amount L being the same as half the y-direction width of the stripe region by moving the XY stage 105. Thus, the shift amount L by which the XY stage 105 is shifted in the y direction is set such that the multiplicity at each position is equal to each other.

Thereby, the lower one-fourth region of the k-th stripe region 32 in the first stripe layer becomes in a quadruple (multiple) written state by being combined with the region located between the one-fourth line and the two-fourths line from the lower side in the (k−1)th stripe region 44 in the fourth stripe layer (the region located between the two-fourths line and the three-fourths line from the lower side in the (k−1)th stripe region 42 in the third stripe layer), and the upper one-fourth region in the (k−1)th stripe region 37 in the second stripe layer.

The region located between the one-fourth line and the two-fourths line from the lower side in the k-th stripe region 32 in the first stripe layer (the lower one-fourth region in the k-th stripe region 37 in the second stripe layer) becomes in a quadruple (multiple) written state by being combined with the region located between the two-fourths line and the three-fourths line from the lower side in the (k−1)th stripe region 44 in the fourth stripe layer (the upper one-fourth region in the (k−1)th stripe regions 42 in the third stripe layer).

The region located between the two-fourths line and the three-fourths line from the lower side in the k-th stripe region 32 in the first stripe layer (the region located between the one-fourth line and the two-fourths line from the lower side in the k-th stripe region 37 in the second stripe layer) becomes in a quadruple (multiple) written state by being combined with the upper one-fourth region in the (k−1)th stripe region 44 in the fourth stripe layer, and the lower one-fourth region in the k-th stripe region 42 in the third stripe layer.

The upper one-fourth region in the k-th stripe region 32 in the first stripe layer (the region located between the two-fourths line and the three-fourths line from the lower side in the k-th stripe region 37 in the second stripe layer) becomes in a quadruple (multiple) written state by being combined with the region located between the two-fourths line and the three-fourths line from the lower side in the k-th stripe region 42 in the third stripe layer (the region located between the one-fourth line and the two-fourths line from the lower side in the k-th stripe region 44 in the fourth stripe layer). By repeating this operation, multiple writing can be performed to each of the stripe regions 32, 37, 42, and 44.

According to the first embodiment, also, in the case of performing quadruple (multiple) writing, since the stage speed is half that of the comparative example, the time taken for one stage movement (one pass) is twice that of it. However, in the first embodiment, the shift amount in the y direction can be made twice that of the comparative example. Further, the number of times of adjustment of the writing starting position, in accordance with the y-direction movement between stripes of the XY stage 105, can be made half of it. Therefore, the adjustment time can be reduced. Accordingly, the writing time can be finally equivalent to or shorter than the case where no y-direction shift is performed.

In the examples described above, deviation (position deviation) of the beam array shape resulting from Y deflection is dynamically corrected using two or more electrostatic lenses 212 and 214, but, it is not limited thereto. For example, position deviation may be corrected by dose modulation. In that case, the writing data processing unit 70 reads chip data (writing data) stored in the storage device 140, and calculates the dose for each pixel. Then, a dose map is generated. Next, the correction unit 71 reads phase data and magnification data from the storage device 140, and obtains a magnification error and a phase deviation in accordance with a set deflection width. Further, the correction unit 71 modulates (corrects) the dose of each pixel in order to obtain a beam array shape in which the magnification error and the phase deviation have been corrected as shown in FIG. 16. The method of modulating the dose may be a conventional method. For example, the beam to irradiate each pixel can be specified according to a preset writing sequence. Then, an irradiation position shift amount of each beam can be coped with by distribution such that the dose corresponding to a deviated area ratio is added to the dose of a pixel, such as an adjacent pixel, located oppositely to the deviated direction.

Next, the writing data processing unit 70 generates irradiation time data for each pixel based on the dose of each pixel after having been modulated. Irradiation time can be obtained by dividing the dose by the current density J. The irradiation time data is rearranged in the order of shots in accordance with a preset writing sequence. The irradiation time data is stored in the storage device 142. The subsequent processing is the same as what is described above.

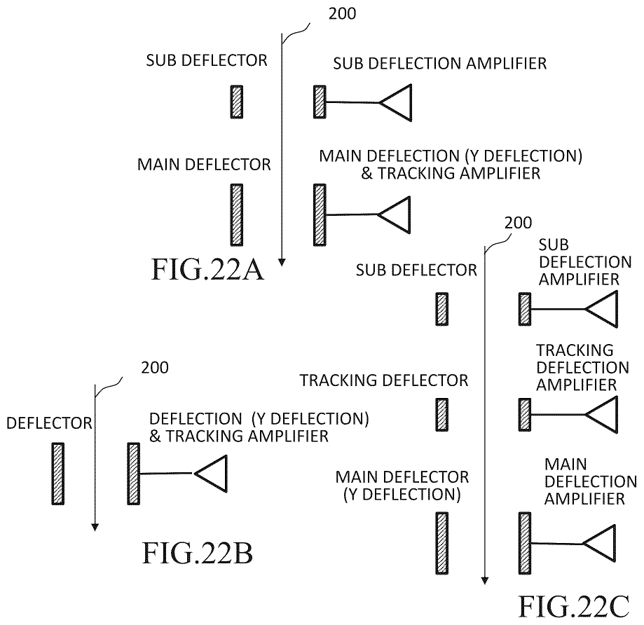

FIGS. 22A to 22C are illustrations explaining a configuration of a deflector according to the first embodiment. In the case of FIG. 1, the multiple beams 20 are deflected by a two-stage deflection of the main deflector 208 and the sub deflector 209 as shown in FIG. 22A. An electric potential is applied to each electrode of the main deflector 208 from the main deflection amplifier (DAC amplifier 134). Similarly, a potential is applied to each electrode of the sub deflector 209 from the sub deflection amplifier (DAC amplifier 132). As described above, the main deflector 208 performs an x-direction tracking control (main deflection X) and a y-direction Y deflection control (main deflection Y). The sub deflector 209 performs an x-direction deflection control (sub deflection X) of each beam irradiation position (the lower left, upper left, lower right, and upper right irradiation positions of 2×2 pixels) in the sub-irradiation region 29, and a y-direction deflection control (sub deflection Y) of each beam irradiation position (the lower left, upper left, lower right, and upper right irradiation positions of 2×2 pixels) in the sub-irradiation region 29.

The configuration of the deflector is not limited to what is described above. For example, as shown in FIG. 22B, all the deflection controls may be performed by a one-stage deflector. Thus, the one-stage deflector performs an x-direction tracking control (main deflection X), a y-direction Y deflection control (main deflection Y), an x-direction deflection control (sub deflection X) of each beam irradiation position (the lower left, upper left, lower right, and upper right irradiation positions of 2×2 pixels) in the sub-irradiation region 29, and a y-direction deflection control (sub deflection Y) of each beam irradiation position (the lower left, upper left, lower right, and upper right irradiation positions of 2×2 pixels) in the sub-irradiation region 29. An electric potential is applied to each electrode of the deflector shown in FIG. 22B from the deflection amplifier.

Alternatively, a three-stage deflector may be used for configuring the deflector as shown in FIG. 22C. For example, a sub deflector, a tracking deflector, and a main deflector are arranged in order from the upstream side of the trajectory of the multiple beams 20. An electric potential is applied to each electrode of the main deflector from the main deflection amplifier. A potential is applied to each electrode of the tracking deflector from the tracking deflection amplifier. A potential is applied to each electrode of the sub deflector from the sub deflection amplifier. The main deflector performs a y-direction Y deflection control (main deflection Y). The tracking deflector performs an x-direction tracking control (main deflection X). The sub deflector 209 performs an x-direction deflection control (sub deflection X) of each beam irradiation position (the lower left, upper left, lower right, and upper right irradiation positions of 2×2 pixels) in the sub-irradiation region 29, and a y-direction deflection control (sub deflection Y) of each beam irradiation position (the lower left, upper left, lower right, and upper right irradiation positions of 2×2 pixels) in the sub-irradiation region 29.

As described above, according to the first embodiment, a position deviation due to displacement of a linear component of a beam array shape in multiple beam writing can be reduced while an increase in a stage moving distance is suppressed.

Embodiments have been explained referring to specific examples described above. However, the present invention is not limited to these specific examples.

While the apparatus configuration, control method, and the like not directly necessary for explaining the present invention are not described, some or all of them can be appropriately selected and used on a case-by-case basis when needed. For example, although description of the configuration of the control unit for controlling the writing apparatus 100 is omitted, it should be understood that some or all of the configuration of the control unit can be selected and used appropriately when necessary.

Further, any multiple charged particle beam writing apparatus and multiple charged particle beam writing method that include elements of the present invention and that can be appropriately modified by those skilled in the art are included within the scope of the present invention.

Additional advantages and modification will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A multiple charged particle beam writing method comprising:
emitting multiple charged particle beams; and
performing writing with the multiple charged particle beams, during a movement of a stage having a target object thereon in a reverse direction to a movement direction of the writing, to at least two stripe regions in a plurality of stripe regions aligned, on the target object, partially overlapping with each other in a first direction being linearly independent with respect to the movement direction of the writing, while repeatedly switching an irradiation region, in the first direction, by a deflection amount having a width larger than a beam pitch size of the multiple charged particle beams, and applying irradiation with the multiple charged particle beams at each time of the switching the irradiation region.

2. The method according to claim 1, wherein
at least during the applying irradiation with the multiple charged particle beams, a tracking control is performed by beam deflection such that the irradiation region of the multiple charged particle beams follows the movement of the stage, and
a switching width of the deflection amount of beam deflection larger than the beam pitch size, in the first direction, is larger than a deflection width of beam deflection in the tracking control.

3. The multiple charged particle beam writing method according to claim 1, further comprising:
correcting a position deviation of a beam array by the multiple charged particle beams, occurring depending on the deflection amount of beam deflection in the first direction, with respect to a shot of the multiple charged particle beams performed while the switching the irradiation region.

4. The method according to claim 1, wherein
a part of the at least two stripe regions is multiply written by the writing to the at least two stripe regions performed during the movement of the stage,
a position of the stage is shifted, after the writing to the at least two stripe regions performed during the movement of the stage, in the first direction so that a part of the at least two stripe regions, which is to be next written, is overlapped with another part of the at least two stripe regions, which has already been written, and
the another part of the at least two stripe regions, being overlapped, is multiply written by performing writing to the at least two stripe regions to be next written.

5. The method according to claim 3, wherein
a shift amount of the stage, in the first direction, is set such that multiplicity of writing at each position is equal to each other.

6. The method according to claim 4, wherein
the width of the deflection amount of beam deflection larger than the beam pitch size, in the first direction, is a half of a shift amount of the stage.

7. A multiple charged particle beam writing apparatus comprising:
a writing mechanism configured to include a beam source which emits multiple charged particle beams, a stage on which a target object is mounted, and a deflector which deflects the multiple charged particle beams, and configured to perform writing with the multiple charged particle beams, during a movement of the stage having the target object thereon in a reverse direction to a movement direction of the writing, to at least two stripe regions in a plurality of stripe regions aligned, on the target object, partially overlapping with each other in a first direction being linearly independent with respect to the movement direction of the writing, while repeatedly switching an irradiation region, in the first direction, by a deflection amount having a width larger than a beam pitch size of the multiple charged particle beams, and applying irradiation with the multiple charged particle beams at each time of the switching the irradiation region; and
a control circuit configured to control the writing mechanism.

8. The apparatus according to one of claim 7, further comprising:
a correction circuit configured to correct a position deviation of a beam array by the multiple charged particle beams, occurring depending on the deflection amount of beam deflection in the first direction, with respect to a shot of the multiple charged particle beams performed while the switching the irradiation region.
